(19) United States
(12) Patent Application Publication
(10) Pub. No.: US 2026/0239942 A1
(43) Pub. Date: Aug. 13, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Yun-Chi CHIANG, Hsinchu (TW); Meng-Pei LU, Hsinchu (TW); Ching-Fu YEH, Hsinchu (TW); Cian-Yu CHEN, Hsinchu (TW); Shin-Yi YANG, Hsinchu (TW)

(73) Assignee: Taiwan Semiconductor Manufacturing Company, Ltd., Hsinchu (TW)

(21) Appl. No.: 19/047,880

(22) Filed: Feb. 7, 2025

(51) Int. Cl. H01L 21/768; H01L 23/522; H01L 23/532

(52) U.S. Cl. CPC H10W 20/033; H10W 20/057; H10W 20/075; H10W 20/42; H10W 20/425

(57) ABSTRACT

A semiconductor structure includes a substrate, a dielectric layer, a barrier layer and a metal layer. The dielectric layer is disposed on the substrate and has a hole. The barrier layer is disposed within the hole. The metal layer is disposed within the hole and in contact with the barrier layer.

### BACKGROUND

Conventional Cu interconnect suffered ramping resistance as the critical line-width (dimension) scales down. Conventional Cu interconnect also encounter bottleneck with the weakness from PVD deposition process. Very hard to directly deposit the copper into the smallest metal-line well, resulting packs of voids and suffered poor yield.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a cross-sectional view of a semiconductor structure according to an embodiment of the present disclosure;

FIG. 2 illustrates a schematic diagram of a cross-sectional view of a semiconductor structure according to another embodiment of the present disclosure;

FIG. 3 illustrates a schematic diagram of a cross-sectional view of a semiconductor structure according to another embodiment of the present disclosure;

FIG. 4 illustrates a schematic diagram of a cross-sectional view of a semiconductor structure according to another embodiment of the present disclosure;

FIG. 5 illustrates a schematic diagram of a cross-sectional view of a semiconductor structure according to another embodiment of the present disclosure;

FIG. 6 illustrates a schematic diagram of a cross-sectional view of a semiconductor structure according to another embodiment of the present disclosure;

FIG. 7 illustrates a schematic diagram of a cross-sectional view of a semiconductor structure according to another embodiment of the present disclosure;

FIG. 8 illustrates a schematic diagram of a cross-sectional view of a semiconductor structure according to another embodiment of the present disclosure;

FIG. 9 illustrates a schematic diagram of a cross-sectional view of a semiconductor structure according to another embodiment of the present disclosure;

FIG. 10 illustrates a schematic diagram of a cross-sectional view of a semiconductor structure according to another embodiment of the present disclosure;

FIG. 11 illustrates a schematic diagram of a cross-sectional view of a semiconductor structure according to another embodiment of the present disclosure;

FIG. 12 illustrates a schematic diagram of a cross-sectional view of a semiconductor structure according to another embodiment of the present disclosure;

FIG. 13 illustrates a schematic diagram of a cross-sectional view of a semiconductor structure according to another embodiment of the present disclosure;

FIG. 14 illustrates a schematic diagram of a cross-sectional view of a semiconductor structure according to another embodiment of the present disclosure;

FIGS. 15A to 15F illustrate schematic diagrams of manufacturing processes of the semiconductor structure in FIG. 1;

FIGS. 16A to 16F illustrate schematic diagrams of manufacturing processes of the semiconductor structure in FIG. 2;

FIGS. 17A to 17F illustrate schematic diagrams of manufacturing processes of the semiconductor structure in FIG. 3;

FIGS. 18A to 18F illustrate schematic diagrams of manufacturing processes of the semiconductor structure in FIG. 4;

FIGS. 19A to 19F illustrate schematic diagrams of manufacturing processes of the semiconductor structure in FIG. 5;

FIGS. 20A to 20F illustrate schematic diagrams of manufacturing processes of the semiconductor structure in FIG. 6;

FIGS. 21A to 21F illustrate schematic diagrams of manufacturing processes of the semiconductor structure in FIG. 7; and

FIGS. 22A to 22G illustrate schematic diagrams of manufacturing processes of the semiconductor structure in FIG. 8.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

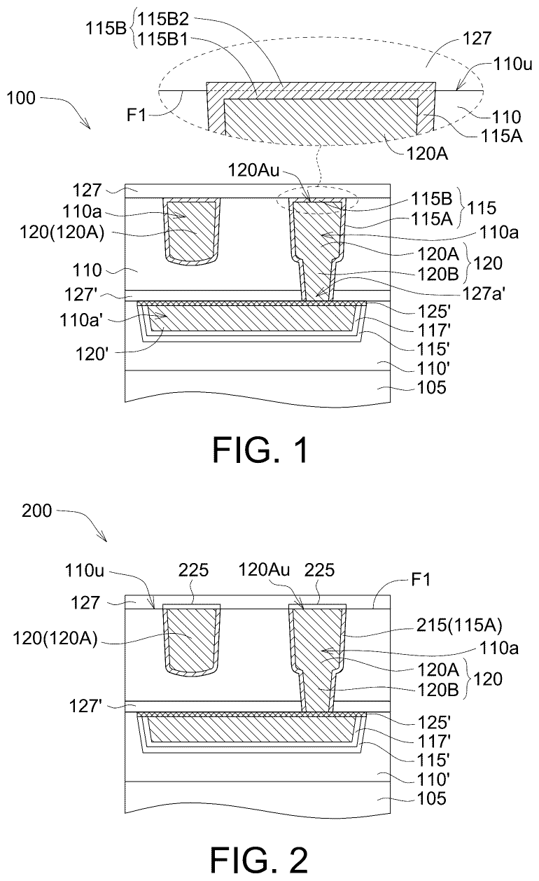

Referring to FIG. 1, FIG. 1 illustrates a schematic diagram of a cross-sectional view of a semiconductor structure 100 according to an embodiment of the present disclosure.

As illustrated in FIG. 1, the semiconductor structure 100 includes a substrate 105, a dielectric layer 110, at least one barrier layer 115, at least one metal layer 120 and at least one etching stop layer (ESL) 127. The dielectric layer 110 is disposed on the substrate 105 and has at least one hole 110a. The barrier layer 115 is disposed within the hole 110a. The metal layer 120 is disposed within he hole 110a and in contact with the barrier layer 115. In the present embodiment, a liner layer between the metal layer 120 and the barrier layer 115 may be omitted, and thus the volume of the metal layer 120 in the hole 110a may be increased and the conductive quality of the metal layer 120 may be improved.

As illustrated in FIG. 1, the semiconductor structure 100 further includes a dielectric layer 110′, a barrier layer 115′, a liner 117′, a metal layer 120′, a capping layer 125′ and an etching stop layer (ESL) 127′. The dielectric layer 110′ has at least one hole 110a′, and the barrier layer 115′, the liner 117′ and the metal layer 120′ are disposed within the hole 110a′, wherein the liner 117′ is formed between the barrier layer 115′ and the metal layer 120′. The liner 117′ may be formed by ALD, CVD and wet coating process. The liner 117′ may be formed of a material including a metal (for example, Co) and/or an alloy (for example, CoW, CoZrTa). The barrier layer 115′ may be formed by ALD, CVD and wet coating process. The barrier layer 115′ may be formed of a material including a metal nitride (for example, TaN), a metal oxide (for example, TiOx) and/or alloy (for example, CoNb). In the present embodiment, the barrier layer 115′ may be formed of a material different from that of the barrier layer 115. The metal layer 120′ may be formed of, for example, copper. The capping layer 125′ is disposed over the metal layer 120′. The etching stop layer 127′ is disposed over the dielectric layer 110′ and the capping layer 125′. The etching stop layer 127′ has at least one opening 127a′, and the metal layer 120 extends to the capping layer 125′ through the opening 127a′.

Although not illustrated, the substrate 105 includes a portion of a silicon wafer, FEOL (front-end-of-line) structure disposed on the silicon wafer and a BEOL (back end of line) structure disposed on the FEOL structure. The dielectric layer 110′, the barrier layer 115′, the liner 117′, the metal layer 120′, the capping layer 125′, the etching stop layer 127′, the dielectric layer 110, the barrier layer 115, the metal layer 120 and the etching stop layer 127 may be a portion of the BEOL structure.

As illustrated in FIG. 1, the barrier layer 115 includes a lateral portion 115A and an upper portion 115B, wherein the lateral portion 115A is formed on a sidewall of the hole 110a, and the upper portion 115B covers an upper surface 120Au of the metal layer 120 and disposed between the etching stop layer 127 and the metal layer 120. In the present embodiment, the barrier layer 115 is formed by a post treatment that drive metal layer material (for example, metal alloy) to self-form an interface (i.e., the barrier layer) between the metal layer itself and the dielectric layer 110.

As illustrated in FIG. 1, the metal layer 120 may react with the etching stop layer 127 to form the upper portion 115B by thermal diffusion in thermal treatment process. Furthermore, the upper portion 115B includes a first portion 115B1 and a second portion 115B2, wherein the first portion 115B1 is formed below an interface F1 between the dielectric layer 110 and the etching stop layer 127, and the second portion 115B2 is formed above the interface F1 by thermal diffusion.

As illustrated in FIG. 1, one or some of the metal layers 120 may extend to the capping layer 125′ and includes a trace portion 120A and a via portion 120B, wherein the via portion 120B connects the trace portion 120A with the metal layer 120′. In an embodiment, the metal layer 120′ may be referred to as MX, while the trace portion 120A of the metal layer 120 located above the metal layer 120′ may be referred to as M_{X+1}, and the via portion 120B may be referred to VX. The subscript “x” may be 0 or a positive integer equal to or greater than 1, for example, 1, 2, 3, 4, 5, 6, . . . , 10, . . . , 20, . . . , etc.

The metal layers 120 may be formed of Cu-based alloy, Co based alloy, Al-based alloy, Ni-based alloy or Ag-based alloy. Cu-based alloy may include Cu—Mn, Cu—Nb, Cu—Ti, Cu—V, Cu—Ta, Cu—Al, Cu—Zn, Cu—Zr, Cu—Er, Cu—Yb, Cu—Y, Cu—W, Cu—Mo, or ternary alloy selected from these elements, or quaternary alloy selected from these elements. Co based alloy may include Co—Mn, Co—Nb, Co—Ti, Co—V, Co—Ta, Co—Al, Co—Zn, Co—Zr, Co—Er, Co—Yb, Co—Y, Co—W, Co—Mo, or ternary alloy selected from these elements, or quaternary alloy selected from these element. Al-based alloy may include Al—Mn, Al—Nb, Al—Ti, Al—V, Al—Ta, Al—Zn, Al—Zr, Al—Er, Al—Yb, Al—Y, Al—W, Al—Mo, Al—Cu, Al—Co, or ternary alloy selected from these elements, or quaternary alloy selected from these elements. Ni-based alloy may include Ni—Mn, Ni—Nb, Ni—Ti, Ni—V, Ni—Ta, Ni—Zn, Ni—Zr, Ni—Er, Ni—Yb, Ni—Y, Ni—W, Ni—Mo, Ni—Al, or ternary alloy selected from these elements, or quaternary alloy selected from these elements. Ag-based alloy may include Ag—Mn, Ag—Nb, Ag—Ti, Ag—V, Ag—Ta, Ag—Zn, Ag—Zr, Ag—Er, Ag—Yb, Ag—Y, Ag—Al, Ag—Mo, Ag—Cu, Ag—Co, or ternary alloy selected from these elements, or quaternary alloy selected from these elements. In an embodiment, the concentration of above-mentioned alloys may range between 0.1% and 99.9%. The aforementioned barrier layer 115 may be formed of the elements from the metal alloys that formed into the compounds including metal-oxide, metal-nitride, metal-carbide, metal-silicide, and metal-silicate. The barrier layer 115 is an electrical insulation. In addition, the barrier layer 115 may provide the functions the same as or similar to that of the aforementioned barrier layer 115′ and the aforementioned liner 117′. In other word, the functions of the barrier layer 115′ and the liner 117′ may be integrated to single barrier layer 115. In an embodiment, the barrier layer 115 has a thickness ranging between, for example, 0.1 nanometers and 10 nanometers, or even less or grater. In addition, the metal layer 120 has a width (or critical dimension) ranging between, for example, 10 nanometers and 1000 nanometers, or even less or grater.

Although not illustrated, the etching stop layer 127 may have at least one opening similar to the opening 127a′ of the etching stop layer 127′, and a similar structure including the dielectric layer 110, the barrier layer 115 and the metal layer 120 may be disposed over the etching stop layer 127.

Referring to FIG. 2, FIG. 2 illustrates a schematic diagram of a cross-sectional view of a semiconductor structure 200 according to another embodiment of the present disclosure.

As illustrated in FIG. 2, the semiconductor structure 200 includes the substrate 105, the dielectric layer 110, at least one barrier layer 215, at least one metal layer 120, at least one capping layer 225, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 215 is disposed within the hole 110a. The metal layer 120 is disposed within he hole 110a and in contact with the barrier layer 215. In the present embodiment, a liner layer between the metal layer 120 and the barrier layer 215 may be omitted, and thus the volume of the metal layer 120 in the hole 110a may be increased and the conductive quality of the metal layer 120 may be improved.

As illustrated in FIG. 2, in the present embodiment, compared to the barrier layer 115, the barrier layer 215 may omit the upper portion 115B. Furthermore, the barrier layer 215 includes the lateral portion 115A, and the lateral portion 115A is formed on the sidewall of the hole 110a. The capping layer 225 is disposed over the metal layer 120, and covers the upper surface 120Au of the trace portion 120A. In the present embodiment, the capping layer 225 is, for example, a non-reactive capping which does not react with the metal layer 120. The capping layer 225 may be formed of a material which does not react with the metal layer 120. In an embodiment, the entirety of the capping layer 225 may protrudes relative to an upper surface 110u of the dielectric layer 110. Alternatively, a portion of the capping layer 225 is embedded in the metal layer 120 (below the interface F1 between the dielectric layer 110 and the etching stop layer 127) and another portion of the capping layer 225 protrudes relative to the upper surface 110u of the dielectric layer 110 (above the interface F1 between the dielectric layer 110 and the etching stop layer 127).

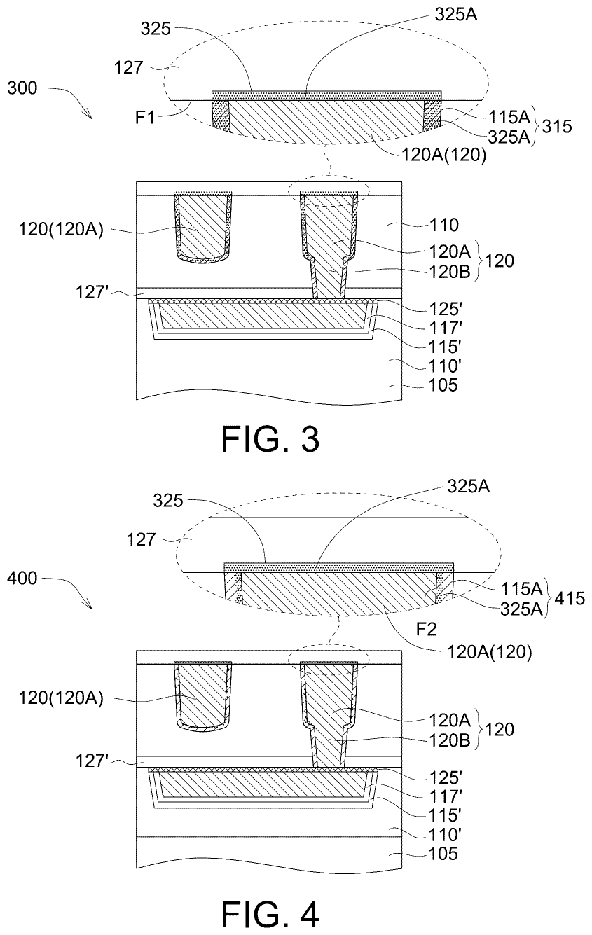

Referring to FIG. 3, FIG. 3 illustrates a schematic diagram of a cross-sectional view of a semiconductor structure 300 according to another embodiment of the present disclosure.

As illustrated in FIG. 3, the semiconductor structure 300 includes the substrate 105, the dielectric layer 110, at least one barrier layer 315, at least one metal layer 120, at least one capping layer 325, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 315 is disposed within the hole 110a. The metal layer 120 is disposed within he hole 110a and in contact with the barrier layer 315. In the present embodiment, a liner layer between the metal layer 120 and the barrier layer 315 be omitted, and thus the volume of the metal layer 120 in the hole 110a may be increased and the conductive quality of the metal layer 120 may be improved.

In the present embodiment, the barrier layer 315 may be formed of a mixed material including the lateral portion 115A and the elements 325A of the capping layer 325. The capping layer 325 is a reactive material with the barrier layer 315. Furthermore, the elements 325A of the capping layer 325 may be diffused into the lateral portion 115A by thermal treatment. The barrier layer 315 is formed on the sidewall of the hole 110a of the dielectric layer 110. In the present embodiment, the capping layer 325 may not react with the etching stop layer 127 and the metal layer 120′ In the present embodiment, the elements 325A of the capping layer 325 is not fully diffused into the lateral portion 115A. In another embodiment, the elements 325A of the capping layer 325 may be fully diffused into the lateral portion 115A, and the capping layer 325 will be exhausted and does not appear on the semiconductor structure 300. In addition, the elements 325A in the lateral portion 115A are dispersedly distributed within the lateral portion 115A.

Referring to FIG. 4, FIG. 4 illustrates a schematic diagram of a cross-sectional view of a semiconductor structure 400 according to another embodiment of the present disclosure.

As illustrated in FIG. 4, the semiconductor structure 400 includes the substrate 105, the dielectric layer 110, at least one barrier layer 415, at least one metal layer 120, at least one capping layer 325, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 415 is disposed within the hole 110a. The metal layer 120 is disposed within he hole 110a and in contact with the barrier layer 415. In the present embodiment, a liner layer between the metal layer 120 and the barrier layer 415 be omitted, and thus the volume of the metal layer 120 in the hole 110a may be increased and the conductive quality of the metal layer 120 may be improved.

In the present embodiment, the barrier layer 415 may be formed of a mixed material including the lateral portion 115A and the elements 325A of the capping layer 325. The capping layer 325 is the reactive material with the barrier layer 315. Furthermore, the elements 325A of the capping layer 325 may be diffused into the lateral portion 115A by thermal treatment. Compared to the barrier layer 315 in FIG. 3, the elements 325A in the lateral portion 115A of FIG. 4 are concentrated adjacent to an interface F2 between the lateral portion 115A and the metal layer 120. The barrier layer 415 is formed on the sidewall of the hole 110a of the dielectric layer 110. In the present embodiment, the capping layer 325 may not react with the etching stop layer 127 and the metal layer 120. In the present embodiment, the elements 325A of the capping layer 325 is not fully diffused into the lateral portion 115A. In another embodiment, the elements 325A of the capping layer 325 may be fully diffused into the lateral portion 115A, and the capping layer 325 will be exhausted and does not appear on the semiconductor structure 400.

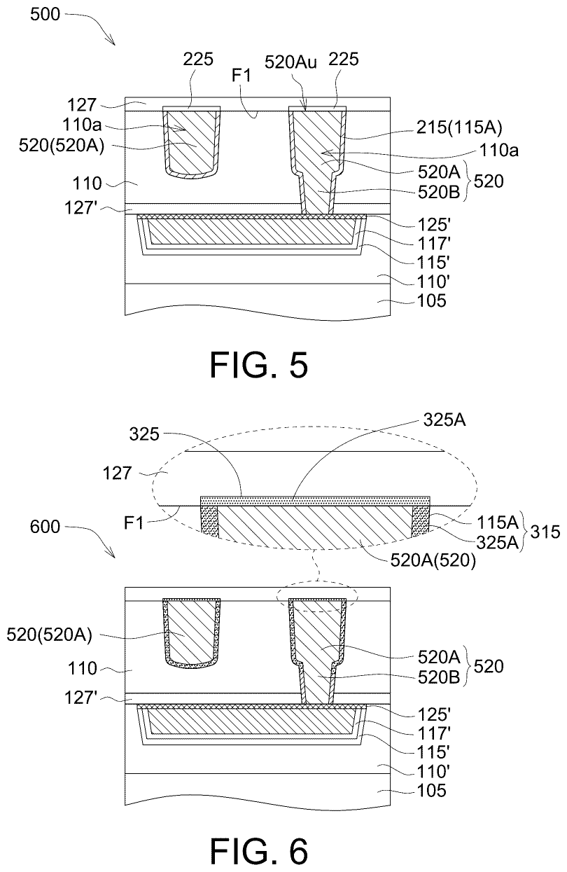

Referring to FIG. 5, FIG. 5 illustrates a schematic diagram of a cross-sectional view of a semiconductor structure 500 according to another embodiment of the present disclosure.

As illustrated in FIG. 5, the semiconductor structure 500 includes the substrate 105, the dielectric layer 110, at least one barrier layer 215, at least one metal layer 520, at least one capping layer 225, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 215 is disposed within the hole 110a. The metal layer 520 is disposed within he hole 110a and in contact with the barrier layer 215. In the present embodiment, a liner layer between the metal layer 520 and the barrier layer 215 be omitted, and thus the volume of the metal layer 520 in the hole 110a may be increased and the conductive quality of the metal layer 120 may be improved.

In the present embodiment, one or some of the metal layers 520 may extend to the capping layer 125′ and includes a trace portion 520A and a via portion 520B, wherein the via portion 520B connects the trace portion 520A with the metal layer 120′. In an embodiment, the metal layer 120′ may be referred to as MX, while the trace portion 520A of the metal layer 520 located above the metal layer 120′ may be referred to as M_{X+1}, and the via portion 520B may be referred to VX.

Compared to the metal layer 120 in FIG. 3, the metal layer 520 in FIG. 5 may be formed of, for example, a metal material whose weight percentage (or concentration) is greater than at least 90%, such as 95%, 98% or even more, wherein the metal material is, for example, copper. The capping layer 225 is disposed over the metal layer 520, and covers the upper surface 520Au of the trace portion 520A. In the present embodiment, the capping layer 225 is, for example, the non-reactive capping which does not react with the metal layer 520. The capping layer 225 may be formed of a material which does not react with the metal layer 520. In an embodiment, the entirety of the capping layer 225 may protrudes relative to the upper surface 110u of the dielectric layer 110. Alternatively, a portion of the capping layer 225 is embedded in the metal layer 520 (below the interface F1 between the dielectric layer 110 and the etching stop layer 127) and another portion of the capping layer 225 protrudes relative to the upper surface 110u of the dielectric layer 110 (above the interface F1 between the dielectric layer 110 and the etching stop layer 127).

Referring to FIG. 6, FIG. 6 illustrates a schematic diagram of a cross-sectional view of a semiconductor structure 600 according to another embodiment of the present disclosure.

As illustrated in FIG. 6, the semiconductor structure 600 includes the substrate 105, the dielectric layer 110, at least one barrier layer 315, at least one metal layer 520, at least one capping layer 325, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 315 is disposed within the hole 110a. The metal layer 520 is disposed within he hole 110a and in contact with the barrier layer 315. In the present embodiment, a liner layer between the metal layer 520 and the barrier layer 315 be omitted, and thus the volume of the metal layer 520 in the hole 110a may be increased and the conductive quality of the metal layer 520 may be improved.

In the present embodiment, the barrier layer 315 may be formed of a mixed material including the barrier layer 115 and the elements 325A of the capping layer 325. The capping layer 325 is a reactive material with the barrier layer 315. Furthermore, the elements 325A of the capping layer 325 may be diffused into the barrier layer 115 by thermal treatment. The barrier layer 315 is formed on the sidewall of the hole 110a of the dielectric layer 110. In the present embodiment, the capping layer 325 may not react with the etching stop layer 127 and the metal layer 520. In the present embodiment, the elements 325A of the capping layer 325 is not fully diffused into the barrier layer 115. In another embodiment, the elements 325A of the capping layer 325 may be fully diffused into the barrier layer 115, and the capping layer 325 will not appear on the metal layer 120. In addition, the elements 325A in the barrier layer 115 are dispersedly distributed within the barrier layer 115.

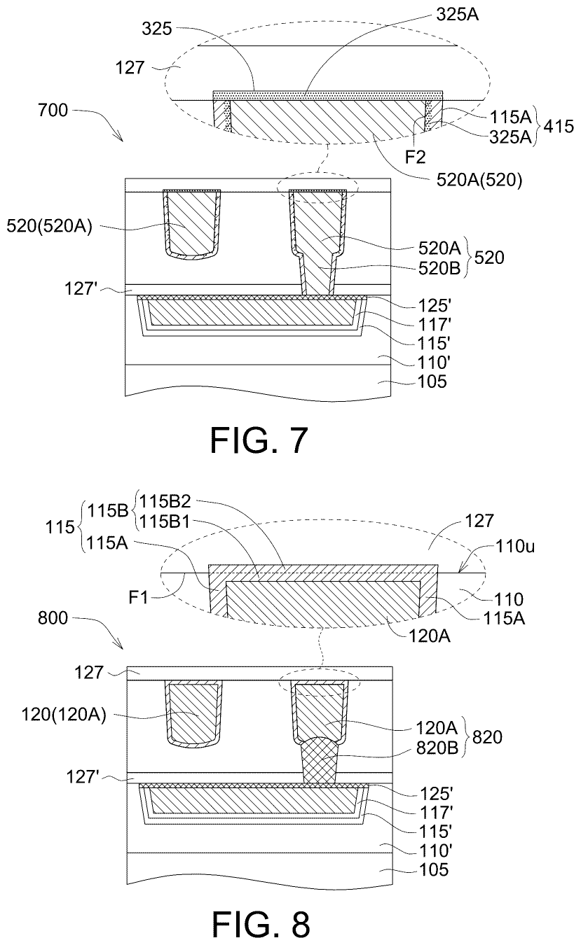

Referring to FIG. 7, FIG. 7 illustrates a schematic diagram of a cross-sectional view of a semiconductor structure 700 according to another embodiment of the present disclosure.

As illustrated in FIG. 7, the semiconductor structure 700 includes the substrate 105, the dielectric layer 110, at least one barrier layer 415, at least one metal layer 520, at least one capping layer 325, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 415 is disposed within the hole 110a. The metal layer 520 is disposed within he hole 110a and in contact with the barrier layer 415. In the present embodiment, a liner layer between the metal layer 520 and the barrier layer 415 be omitted, and thus the volume of the metal layer 520 in the hole 110a may be increased and the conductive quality of the metal layer 520 may be improved.

In the present embodiment, the barrier layer 415 may be formed of a mixed material including the barrier layer 115 and the elements 325A of the capping layer 325. The capping layer 325 is the reactive material with the barrier layer 315. Furthermore, the elements 325A of the capping layer 325 may be diffused into the barrier layer 115 by thermal treatment. Compared to the barrier layer 315 in FIG. 3, the elements 325A in the barrier layer 115 of FIG. 4 are concentrated adjacent to an interface F2 between the barrier layer 115 and the metal layer 520. The barrier layer 415 is formed on the sidewall of the hole 110a of the dielectric layer 110. In the present embodiment, the capping layer 325 may not react with the etching stop layer 127 and the metal layer 520. In the present embodiment, the elements 325A of the capping layer 325 is not fully diffused into the barrier layer 115. In another embodiment, the elements 325A of the capping layer 325 may be fully diffused into the barrier layer 115, and the capping layer 325 will not appear on the metal layer 520.

Referring to FIG. 8, FIG. 8 illustrates a schematic diagram of a cross-sectional view of a semiconductor structure 800 according to another embodiment of the present disclosure.

As illustrated in FIG. 8, the semiconductor structure 800 includes the substrate 105, the dielectric layer 110, at least one barrier layer 115, at least one metal layer 820, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 115 is disposed within the hole 110a. The metal layer 820 is disposed within he hole 110a and in contact with the barrier layer 115. In the present embodiment, a liner layer between the metal layer 820 and the barrier layer 115 may be omitted, and thus the volume of the metal layer 820 in the hole 110a may be increased and the conductive quality of the metal layer 820 may be improved.

Compared to the semiconductor structure 100 in FIG. 1, the metal layer 820 of the semiconductor structure 800 is a multi-layered structure. Furthermore, the metal layer 820 includes the trace portion 120A and a via portion 820B, wherein the via portion 820B is disposed a lower portion of the hole 110a, the trace portion 120A is disposed an upper portion of the hole 110a. The trace portion 120A and the via portion 820B are different in material. The via portion 820B may be formed of a material including tungsten (W), Ruthenium (Ru), Molybdenum (Mo) or a combination thereof. The via portion 820B is in directly contact with the sidewall of hole 110a. The lateral portion 115A of the barrier layer 115 is disposed between the trace portion 120A of the metal layer 120 and the dielectric layer 110. In the present embodiment, a portion of the barrier layer 115 (for example, electrical insulation) may be omitted between the via portion 820B and the sidewall of the hole 110a, and thus it may increase overall conductivity of the metal layer 820 (the volume of the via portion 820B is greater than that of the via portion 120B of the metal layer 120 in FIG. 1). In addition, the via portion 820B does not react with the dielectric layer 110 and the etching stop layer 127 and the capping layer 125′.

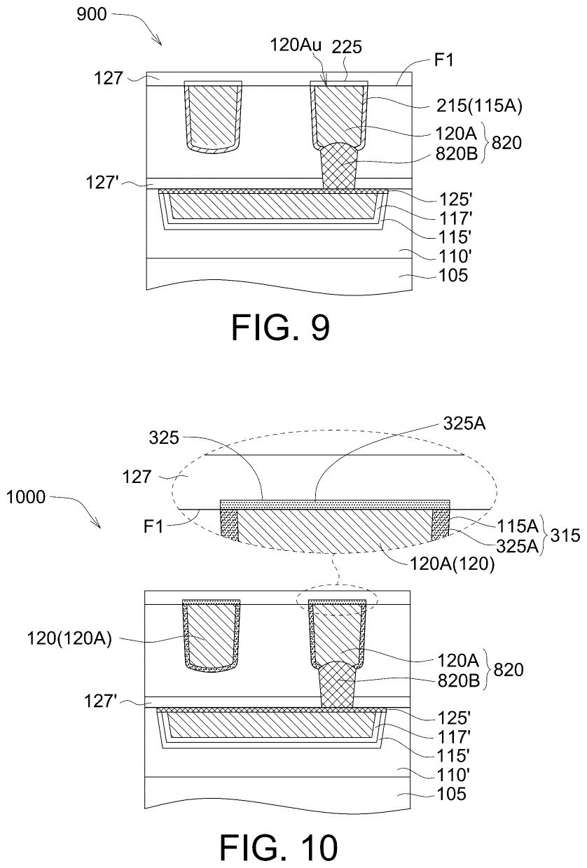

Referring to FIG. 9, FIG. 9 illustrates a schematic diagram of a cross-sectional view of a semiconductor structure 900 according to another embodiment of the present disclosure.

As illustrated in FIG. 9, the semiconductor structure 900 includes the substrate 105, the dielectric layer 110, at least one barrier layer 215, at least one metal layer 820, at least one capping layer 225, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 215 is disposed within the hole 110a. The metal layer 820 is disposed within he hole 110a and in contact with the barrier layer 215. In the present embodiment, a liner layer between the metal layer 820 and the barrier layer 215 may be omitted, and thus the volume of the metal layer 820 in the hole 110a may be increased and the conductive quality of the metal layer 820 may be improved.

Compared to the semiconductor structure 200 in FIG. 2, the metal layer 820 of the semiconductor structure 900 is a multi-layered structure. Furthermore, the metal layer 820 includes the trace portion 120A and the via portion 820B. The trace portion 120A and the via portion 820B are different in material. The via portion 820B may be formed of a material including W, Ru, Mo or a combination thereof. The via portion 820B is in directly contact with the sidewall of hole 110a. In the present embodiment, a portion of the barrier layer 215 (for example, electrical insulation) may be omitted between the via portion 820B and the sidewall of the hole 110a, and thus it may increase overall conductivity of the metal layer 820 (the volume of the via portion 820B is greater than that of the via portion 120B of the metal layer 120 in FIG. 2). In addition, the via portion 820B does not react with the dielectric layer 110 and the etching stop layer 127 and the capping layer 125′.

Referring to FIG. 10, FIG. 10 illustrates a schematic diagram of a cross-sectional view of a semiconductor structure 1000 according to another embodiment of the present disclosure.

As illustrated in FIG. 10, the semiconductor structure 1000 includes the substrate 105, the dielectric layer 110, at least one barrier layer 315, at least one metal layer 120, at least one capping layer 325, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 315 is disposed within the hole 110a. The metal layer 820 is disposed within he hole 110a and in contact with the barrier layer 315. In the present embodiment, a liner layer between the metal layer 820 and the barrier layer 315 be omitted, and thus the volume of the metal layer 820 in the hole 110a may be increased and the conductive quality of the metal layer 820 may be improved.

In the present embodiment, the barrier layer 315 may be formed of a mixed material including the lateral portion 115A and the elements 325A of the capping layer 325. The capping layer 325 is a reactive material with the barrier layer 315. Furthermore, the elements 325A of the capping layer 325 may be diffused into the lateral portion 115A by thermal treatment. The barrier layer 315 is formed on the sidewall of the hole 110a of the dielectric layer 110. In the present embodiment, the capping layer 325 may not react with the etching stop layer 127 and the metal layer 120. In the present embodiment, the elements 325A of the capping layer 325 is not fully diffused into the lateral portion 115A. In another embodiment, the elements 325A of the capping layer 325 may be fully diffused into the lateral portion 115A, and the capping layer 325 will be exhausted and does not appear on the semiconductor structure 1000. In addition, the elements 325A in the lateral portion 115A are dispersedly distributed within the lateral portion 115A.

Compared to the semiconductor structure 300 in FIG. 3, the metal layer 820 of the semiconductor structure 1000 is a multi-layered structure. Furthermore, the metal layer 820 includes the trace portion 120A and the via portion 820B. The trace portion 120A and the via portion 820B are different in material. The via portion 820B may be formed of a material including W, Ru, Mo or a combination thereof. The via portion 820B is in directly contact with the sidewall of hole 110a. In the present embodiment, a portion of the barrier layer 315 (for example, electrical insulation) may be omitted between the via portion 820B and the sidewall of the hole 110a, and thus it may increase overall conductivity of the metal layer 820 (the volume of the via portion 820B is greater than that of the via portion 120B of the metal layer 120 in FIG. 3). In addition, the via portion 820B does not react with the dielectric layer 110 and the etching stop layer 127 and the capping layer 125′.

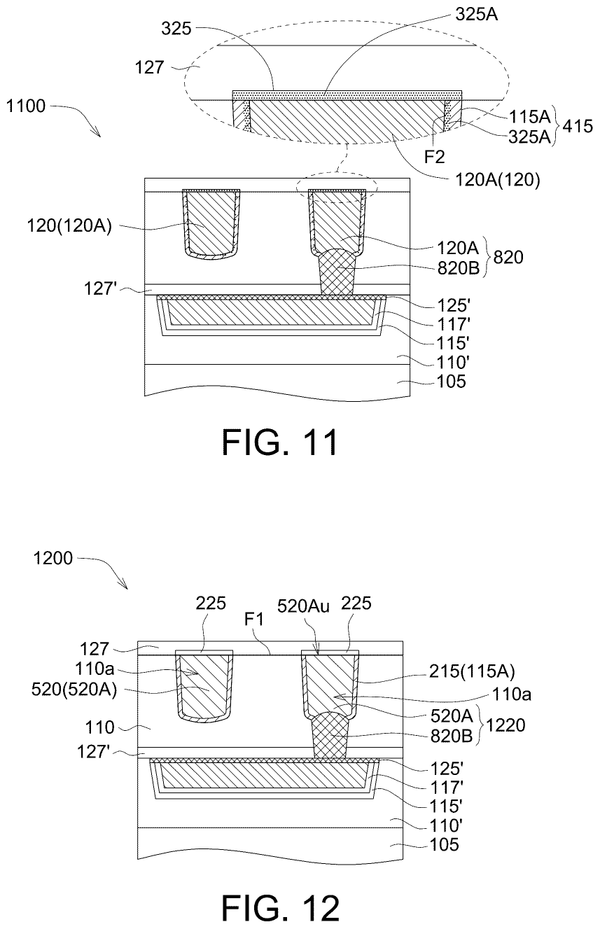

Referring to FIG. 11, FIG. 11 illustrates a schematic diagram of a cross-sectional view of a semiconductor structure 1100 according to another embodiment of the present disclosure.

As illustrated in FIG. 11, the semiconductor structure 1100 includes the substrate 105, the dielectric layer 110, at least one barrier layer 415, at least one metal layer 120, at least one capping layer 325, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 415 is disposed within the hole 110a. The metal layer 820 is disposed within he hole 110a and in contact with the barrier layer 415. In the present embodiment, a liner layer between the metal layer 820 and the barrier layer 415 be omitted, and thus the volume of the metal layer 820 in the hole 110a may be increased and the conductive quality of the metal layer 820 may be improved.

In the present embodiment, the barrier layer 415 may be formed of a mixed material including the lateral portion 115A and the elements 325A of the capping layer 325. The capping layer 325 is the reactive material with the barrier layer 315. Furthermore, the elements 325A of the capping layer 325 may be diffused into the lateral portion 115A by thermal treatment. Compared to the barrier layer 315 in FIG. 3, the elements 325A in the lateral portion 115A of FIG. 4 are concentrated adjacent to an interface F2 between the lateral portion 115A and the metal layer 820. The barrier layer 415 is formed on the sidewall of the hole 110a of the dielectric layer 110. In the present embodiment, the capping layer 325 may not react with the etching stop layer 127 and the metal layer 820. In the present embodiment, the elements 325A of the capping layer 325 is not fully diffused into the lateral portion 115A. In another embodiment, the elements 325A of the capping layer 325 may be fully diffused into the lateral portion 115A, and the capping layer 325 will be exhausted and does not appear on the semiconductor structure 1100.

Compared to the semiconductor structure 400 in FIG. 4, the metal layer 820 of the semiconductor structure 1100 is a multi-layered structure. Furthermore, the metal layer 820 includes the trace portion 120A and the via portion 820B. The trace portion 120A and the via portion 820B are different in material. The via portion 820B may be formed of a material including W, Ru, Mo or a combination thereof. The via portion 820B is in directly contact with the sidewall of hole 110a. In the present embodiment, a portion of the barrier layer 415 (for example, electrical insulation) may be omitted between the via portion 820B and the sidewall of the hole 110a, and thus it may increase overall conductivity of the metal layer 820 (the volume of the via portion 820B is greater than that of the via portion 120B of the metal layer 120 in FIG. 4). In addition, the via portion 820B does not react with the dielectric layer 110 and the etching stop layer 127 and the capping layer 125′.

Referring to FIG. 12, FIG. 12 illustrates a schematic diagram of a cross-sectional view of a semiconductor structure 1200 according to another embodiment of the present disclosure.

As illustrated in FIG. 12, the semiconductor structure 1200 includes the substrate 105, the dielectric layer 110, at least one barrier layer 215, at least one metal layer 1220, at least one capping layer 225, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 215 is disposed within the hole 110a. The metal layer 1220 is disposed within he hole 110a and in contact with the barrier layer 215. In the present embodiment, a liner layer between the metal layer 1220 and the barrier layer 215 be omitted, and thus the volume of the metal layer 1220 in the hole 110a may be increased and the conductive quality of the metal layer 120 may be improved.

In the present embodiment, one or some of the metal layers 1220 may extend to the capping layer 125′ and includes the trace portion 520A and the via portion 820B, wherein the via portion 820B connects the trace portion 520A with the metal layer 120′. In an embodiment, the metal layer 120′ may be referred to as MX, while the trace portion 520A of the metal layer 1220 located above the metal layer 120′ may be referred to as M_{X+1}, and the via portion 820B may be referred to VX.

Compared to the metal layer 120 in FIG. 10, the via portion 820B of the metal layer 1220 in FIG. 12 may be formed of, for example, a metal material whose weight percentage (or concentration) is greater than at least 90%, such as 95%, 98% or even more, wherein the metal material is, for example, copper. The capping layer 225 is disposed over the metal layer 1220, and covers the upper surface 520Au of the trace portion 520A of the metal layer 1220. In the present embodiment, the capping layer 225 is, for example, the non-reactive capping which does not react with the metal layer 1220. The capping layer 225 may be formed of a material which does not react with the metal layer 1220. In an embodiment, the entirety of the capping layer 225 may protrudes relative to the upper surface 110u of the dielectric layer 110(Alternatively, a portion of the capping layer 225 is embedded in the metal layer 1220 (below the interface F1 between the dielectric layer 110 and the etching stop layer 127) and another portion of the capping layer 225 protrudes relative to the upper surface 110u of the dielectric layer 110 (above the interface F1 between the dielectric layer 110 and the etching stop layer 127).

Compared to the semiconductor structure 500 in FIG. 5, the metal layer 1220 of the semiconductor structure 1200 is a multi-layered structure. Furthermore, the metal layer 1220 includes the trace portion 520A and the via portion 820B. The trace portion 520A and the via portion 820B are different in material. The via portion 820B may be formed of a material including W, Ru, Mo or a combination thereof. The via portion 820B is in directly contact with the sidewall of hole 110a. In the present embodiment, a portion of the barrier layer 415 (for example, electrical insulation) may be omitted between the via portion 820B and the sidewall of the hole 110a, and thus it may increase overall conductivity of the metal layer 1220 (the volume of the via portion 820B is greater than that of the via portion 520B of the metal layer 520 in FIG. 5). In addition, the via portion 820B does not react with the dielectric layer 110 and the etching stop layer 127 and the capping layer 125′.

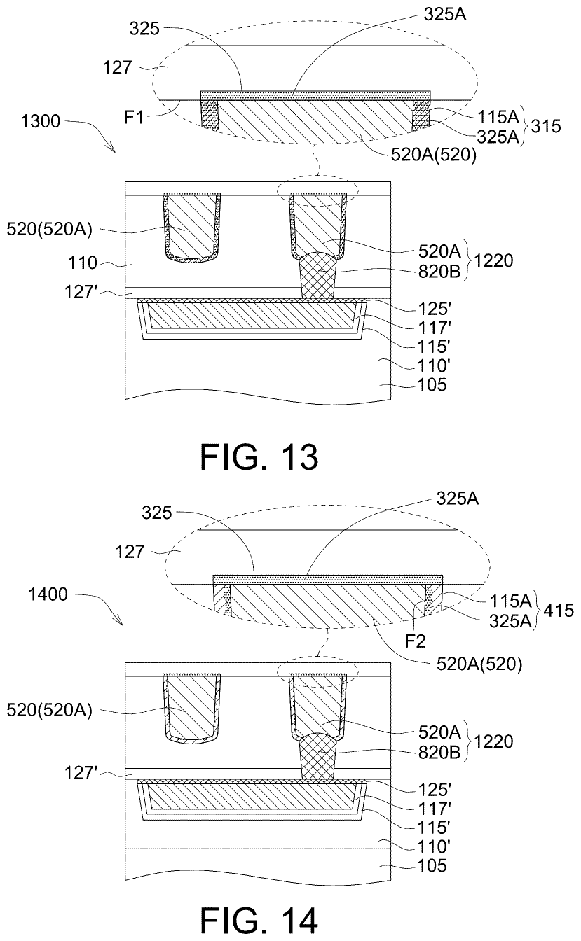

Referring to FIG. 13, FIG. 13 illustrates a schematic diagram of a cross-sectional view of a semiconductor structure 1300 according to another embodiment of the present disclosure.

As illustrated in FIG. 13, the semiconductor structure 1300 includes the substrate 105, the dielectric layer 110, at least one barrier layer 315, at least one metal layer 1220, at least one capping layer 325, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 315 is disposed within the hole 110a. The metal layer 1220 is disposed within he hole 110a and in contact with the barrier layer 315. In the present embodiment, a liner layer between the metal layer 1220 and the barrier layer 315 be omitted, and thus the volume of the metal layer 1220 in the hole 110a may be increased and the conductive quality of the metal layer 1220 may be improved.

In the present embodiment, the barrier layer 315 may be formed of a mixed material including the barrier layer 115 and the elements 325A of the capping layer 325. The capping layer 325 is a reactive material with the barrier layer 315. Furthermore, the elements 325A of the capping layer 325 may be diffused into the barrier layer 115 by thermal treatment. The barrier layer 315 is formed on the sidewall of the hole 110a of the dielectric layer 110. In the present embodiment, the capping layer 325 may not react with the etching stop layer 127 and the metal layer 1220. In the present embodiment, the elements 325A of the capping layer 325 is not fully diffused into the barrier layer 115. In another embodiment, the elements 325A of the capping layer 325 may be fully diffused into the barrier layer 115, and the capping layer 325 will not appear on the metal layer 120. In addition, the elements 325A in the barrier layer 115 are dispersedly distributed within the barrier layer 115.

Compared to the semiconductor structure 600 in FIG. 6, the metal layer 1220 of the semiconductor structure 1300 is a multi-layered structure. Furthermore, the metal layer 1220 includes the trace portion 520A and the via portion 820B. The trace portion 520A and the via portion 820B are different in material. The via portion 820B may be formed of a material including W, Ru, Mo or a combination thereof. The via portion 820B is in directly contact with the sidewall of hole 110a. In the present embodiment, a portion of the barrier layer 415 (for example, electrical insulation) may be omitted between the via portion 820B and the sidewall of the hole 110a, and thus it may increase overall conductivity of the metal layer 1220 (the volume of the via portion 820B is greater than that of the via portion 520B of the metal layer 520 in FIG. 6). In addition, the via portion 820B does not react with the dielectric layer 110 and the etching stop layer 127 and the capping layer 125′.

Referring to FIG. 14, FIG. 14 illustrates a schematic diagram of a cross-sectional view of a semiconductor structure 1400 according to another embodiment of the present disclosure.

As illustrated in FIG. 14, the semiconductor structure 1400 includes the substrate 105, the dielectric layer 110, at least one barrier layer 415, at least one metal layer 1220, at least one capping layer 325, at least one etching stop layer 127, the dielectric layer 110′, the barrier layer 115′, the liner 117′, the metal layer 120′, the capping layer 125′ and the etching stop layer 127′. The dielectric layer 110 is disposed on the substrate 105 and has at least one hole 110a. The barrier layer 415 is disposed within the hole 110a. The metal layer 1220 is disposed within he hole 110a and in contact with the barrier layer 415. In the present embodiment, a liner layer between the metal layer 1220 and the barrier layer 415 be omitted, and thus the volume of the metal layer 1220 in the hole 110a may be increased and the conductive quality of the metal layer 1220 may be improved.

In the present embodiment, the barrier layer 415 may be formed of a mixed material including the barrier layer 115 and the elements 325A of the capping layer 325. The capping layer 325 is the reactive material with the barrier layer 315. Furthermore, the elements 325A of the capping layer 325 may be diffused into the barrier layer 115 by thermal treatment. Compared to the barrier layer 315 in FIG. 13, the elements 325A in the barrier layer 115 of FIG. 14 are concentrated adjacent to an interface F2 between the barrier layer 115 and the metal layer 1220. The barrier layer 415 is formed on the sidewall of the hole 110a of the dielectric layer 110. In the present embodiment, the capping layer 325 may not react with the etching stop layer 127 and the metal layer 1220. In the present embodiment, the elements 325A of the capping layer 325 is not fully diffused into the barrier layer 115. In another embodiment, the elements 325A of the capping layer 325 may be fully diffused into the barrier layer 115, and the capping layer 325 will not appear on the metal layer 1220.

Compared to the semiconductor structure 700 in FIG. 7, the metal layer 1220 of the semiconductor structure 1400 is a multi-layered structure. Furthermore, the metal layer 1220 includes the trace portion 520A and the via portion 820B. The trace portion 520A and the via portion 820B are different in material. The via portion 820B may be formed of a material including W, Ru, Mo or a combination thereof. The via portion 820B is in directly contact with the sidewall of hole 110a. In the present embodiment, a portion of the barrier layer 415 (for example, electrical insulation) may be omitted between the via portion 820B and the sidewall of the hole 110a, and thus it may increase overall conductivity of the metal layer 1220 (the volume of the via portion 820B is greater than that of the via portion 520B of the metal layer 520 in FIG. 7). In addition, the via portion 820B does not react with the dielectric layer 110 and the etching stop layer 127 and the capping layer 125′.

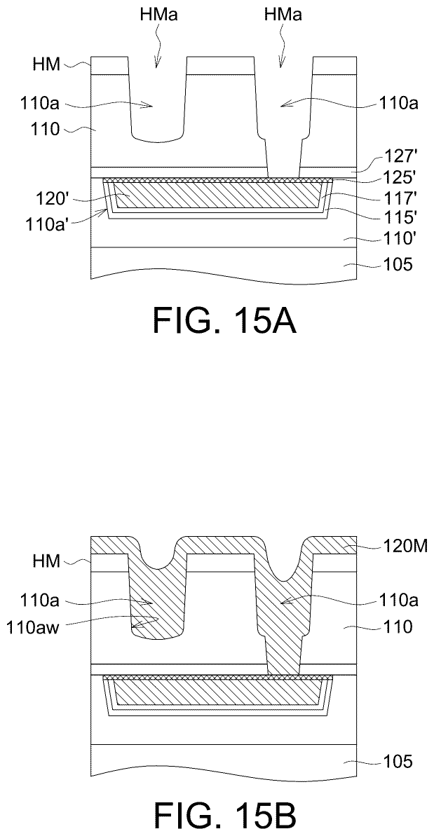

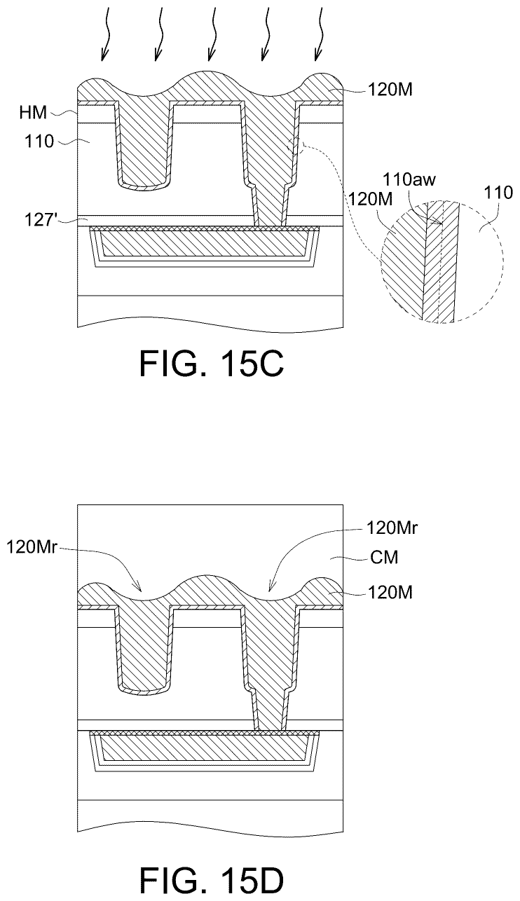

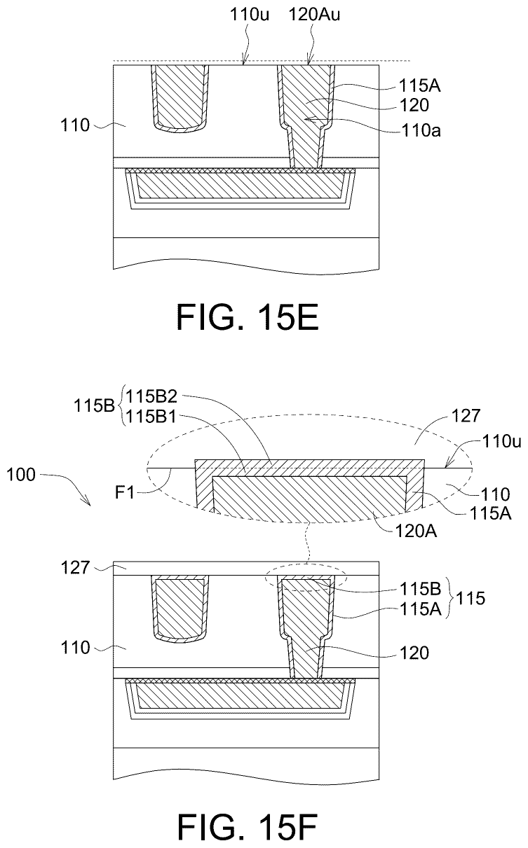

Referring to FIGS. 15A to 15F, FIGS. 15A to 15F illustrate schematic diagrams of manufacturing processes of the semiconductor structure 100 in FIG. 1.

As illustrated in FIG. 15A, the dielectric layer 110′, the barrier layer 115′, the liner 117′, the metal layer 120′, the capping layer 125′ and the etching stop layer 127′ are formed on the substrate 105′. The dielectric layer 110′ has at least one hole 110a′, and the barrier layer 115′, the liner 117′ and the metal layer 120′ are formed within the hole 110a′, wherein the liner 117′ is formed between the barrier layer 115′ and the metal layer 120′. The liner 117′ may be formed by CVD (Chemical Vapor Deposition), ALD (Atomic Layer Deposition), PVD (Physical Vapor Deposition) and/or wet coating process. The liner 117′ may be formed of a material including a metal (for example, Co) and/or an alloy (for example, CoW, CoZrTa). The barrier layer 115′ may be formed by ALD, CVD, PVD and/or wet coating process. The barrier layer 115′ the may be formed of a material including a metal nitride (for example, TaN), a metal oxide (for example, TiOx) and/or alloy (for example, CoNb). The capping layer 125′ is disposed over the metal layer 120′. The etching stop layer 127′ is disposed over the dielectric layer 110′ and the capping layer 125′. The etching stop layer 127′ has at least one opening 127a′, and the metal layer 120 extends to the capping layer 125′ through the opening 127a′.

In FIG. 15A, the dielectric layer 110 is formed over the etching stop layer 127′ by using, for example, deposition, etc. Then, a patterned hard mask HM having at least one opening HMa is formed on the dielectric layer 110. Then, the dielectric layer 110 is patterned to form at least one hole 110a through the opening HMa by using, for example, etching, etc. One or some of the holes 110a is blind hole, and/or another or some of the holes 110a is through hole which passes through the etching stop layer 127′ and extends to the capping layer 125′.

As illustrated in FIG. 15B, a metal layer material 120M over the hard mask HM is formed by using, for example, deposition, such as CVD, PVD, ALD, etc.

As illustrated in FIG. 15C, the metal layer material 120M is treated by a post treatment that drive metal the metal layer material 120M to be self-formed between itself and the dielectric layer 110. Furthermore, the metal layer material 120M may be heated to a temperature ranging between, for example, room temperature and 1000° C. (for example, 300° C. to 400° C.) to form a barrier material 115M. The barrier material 115M is formed on an interface between the dielectric layer 110 and the metal layer material 120M, an interface between the hard mask HM and the metal layer material 120M and an interface between the etching stop layer 127 and the metal layer material 120M. After being heated, the metal layer material 120M becomes flowable and fills up the entirety of the holes 110a. As a result, even a pitch between adjacent two holes 110a is very fine (for example, 10 nanometers to 50 nanometers), the flowable metal layer material 120M still can fill up the entirety of such holes 110a.

In FIG. 15C, by the thermal driving in the post treatment, the material of the metal layer 120M may diffuse to the dielectric layer 110 through the sidewall 110aw of the hole 110a in FIG. 15B, and the material of the dielectric layer 110 may diffuse to the metal layer 120M through the sidewall 110aw of the hole 110a in FIG. 15B, and the material (or element) of the metal layer 120M and the material (or element) of the dielectric layer 110 chemically react with each other to form the barrier layer 115.

In an embodiment, the metal layer material 120M may be formed by using at least one process cycle, wherein the process cycle includes the aforementioned deposition and the aforementioned post treatment. Each process cycle may form a part of the metal layer material 120M, and the entirety of the metal layer material 120M is formed after all of the at least one process cycles is completed.

In terms of material, the metal layer material 120M may be formed of Cu-based alloy, Co based alloy, Al-based alloy, Ni-based alloy or Ag-based alloy. Cu-based alloy may include Cu—Mn, Cu—Nb, Cu—Ti, Cu—V, Cu—Ta, Cu—Al, Cu—Zn, Cu—Zr, Cu—Er, Cu—Yb, Cu—Y, Cu—W, Cu—Mo, or ternary alloy selected from these elements, or quaternary alloy selected from these elements. Co based alloy may include Co—Mn, Co—Nb, Co—Ti, Co—V, Co—Ta, Co—Al, Co—Zn, Co—Zr, Co—Er, Co—Yb, Co—Y, Co—W, Co—Mo, or ternary alloy selected from these elements, or quaternary alloy selected from these element. Al-based alloy may include Al—Mn, Al—Nb, Al—Ti, Al—V, Al—Ta, Al—Zn, Al—Zr, Al—Er, Al—Yb, Al—Y, Al—W, Al—Mo, Al—Cu, Al—Co, or ternary alloy selected from these elements, or quaternary alloy selected from these elements. Ni-based alloy may include Ni—Mn, Ni—Nb, Ni—Ti, Ni—V, Ni—Ta, Ni—Zn, Ni—Zr, Ni—Er, Ni—Yb, Ni—Y, Ni—W, Ni—Mo, Ni—Al, or ternary alloy selected from these elements, or quaternary alloy selected from these elements. Ag-based alloy may include Ag—Mn, Ag—Nb, Ag—Ti, Ag—V, Ag—Ta, Ag—Zn, Ag—Zr, Ag—Er, Ag—Yb, Ag—Y, Ag—Al, Ag—Mo, Ag—Cu, Ag—Co, or ternary alloy selected from these elements, or quaternary alloy selected from these elements. In an embodiment, the concentration of above-mentioned alloys may range between 0.1% and 99.9%.

As illustrated in FIG. 15D, a covering layer CM over the metal layer material 120M is formed by using, for example, deposition, such as ALD, PVD, CVD, etc. After the metal layer material 120M is solidified, the metal layer material 120M has at least one recess 120Mr. The covering layer CM may fill up the recess 120Mr for obtaining a planarized surface in a CMP (Chemical-Mechanical Planarization).

As illustrated in FIG. 15E, the hard mask HM, the covering layer CM, a portion of the metal layer material 120M and a portion of the barrier material 115M is removed by using, for example, CMP. The remaining portion of the metal layer material 120M forms the metal layer 120, and the remaining portion of the barrier material 115M forms the lateral portion 115A which is formed on the sidewall of the hole 110a. After CMP, the dielectric layer 110 forms the upper surface 110u, and the metal layer 120 forms the upper surface 120Au, wherein the upper surface 110u and the upper surface 120Au are aligned with (for example, flushed) each other.

As illustrated in FIG. 15F, the etching stop layer 127 over the dielectric layer 110 and the metal layer 120 is formed to form the semiconductor structure 100 by using, for example, deposition, such as ALD, PVD, CVD, etc. The etching stop layer 127 is formed at a temperature, for example, 300° C. to 400° C. to form the upper portion 115B by thermal diffusion. In other words, the metal layer 120 may react with the etching stop layer 127 to form the upper portion 115B. The upper portion 115B includes the first portion 115B1 and the second portion 115B2, wherein the first portion 115B1 is formed below the interface F1 between the dielectric layer 110 and the etching stop layer 127, and the second portion 115B2 is formed above the interface F1.

In another embodiment, another dielectric layer 110, another barrier layer 115 and another metal layer 120 may be formed on the etching stop layer 127 by using the processes the same as or similar to that of the aforementioned dielectric layer 110, the barrier layer 115 and the metal layer 120. In another embodiment, if not necessary, the etching stop layer 127 in FIG. 15F may be omitted.

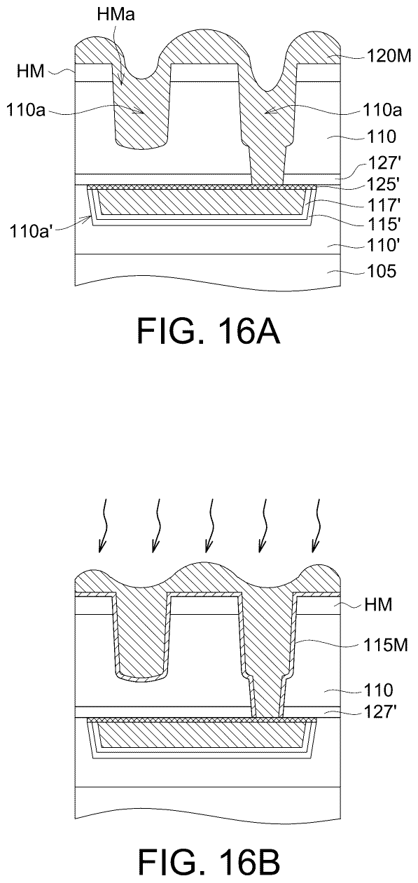

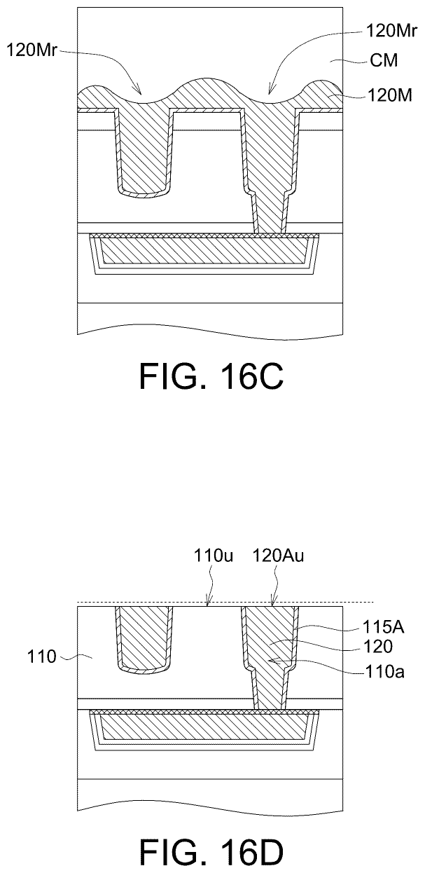

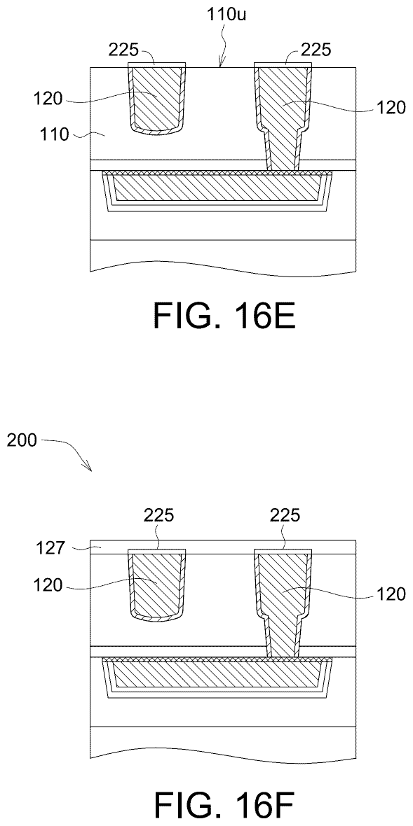

Referring to FIGS. 16A to 16F, FIGS. 16A to 16F illustrate schematic diagrams of manufacturing processes of the semiconductor structure 200 in FIG. 2.

As illustrated in FIG. 16A, the dielectric layer 110′, the barrier layer 115′, the liner 117′, the metal layer 120′, the capping layer 125′ and the etching stop layer 127′ are formed on the substrate 105′. The dielectric layer 110′ has at least one hole 110a′, and the barrier layer 115′, the liner 117′ and the metal layer 120′ are formed within the hole 110a′, wherein the liner 117′ is formed between the barrier layer 115′ and the metal layer 120′. The liner 117′ may be formed by CVD (Chemical Vapor Deposition), ALD (Atomic Layer Deposition), PVD (Physical Vapor Deposition) and/or wet coating process. The liner 117′ may be formed of a material including a metal (for example, Co) and/or an alloy (for example, CoW, CoZrTa). The barrier layer 115′ may be formed by ALD, CVD, PVD and/or wet coating process. The barrier layer 115′ the may be formed of a material including a metal nitride (for example, TaN), a metal oxide (for example, TiOx) and/or alloy (for example, CoNb). The capping layer 125′ is disposed over the metal layer 120′. The etching stop layer 127′ is disposed over the dielectric layer 110′ and the capping layer 125′. The etching stop layer 127′ has at least one opening 127a′, and the metal layer 120′ extends to the capping layer 125′ through the opening 127a′.

In FIG. 16A, the dielectric layer 110 is formed over the etching stop layer 127′ by using, for example, deposition, etc. Then, a patterned hard mask HM having at least one opening HMa is formed on the dielectric layer 110. Then, the dielectric layer 110 is patterned to form at least one hole 110a through the opening HMa by using, for example, etching, etc. One or some of the holes 110a is blind hole, and/or another or some of the holes 110a is through hole which passes through the etching stop layer 127′ and extends to the capping layer 125′. Then, the metal layer material 120M over the hard mask HM is formed by using, for example, deposition, such as CVD, PVD, ALD, etc.

As illustrated in FIG. 16B, the metal layer material 120M is treated by a post treatment that drive metal the metal layer material 120M to be self-formed between itself and the dielectric layer 110. Furthermore, the metal layer material 120M may be heated to a temperature ranging between, for example, room temperature and 1000° C. (for example, 300° C. to 400° C.) to form the barrier material 115M. The barrier material 115M is formed on an interface between the dielectric layer 110 and the metal layer material 120M, an interface between the hard mask HM and the metal layer material 120M and an interface between the etching stop layer 127 and the metal layer material 120M. After being heated, the metal layer material 120M becomes flowable and fills up the entirety of the holes 110a. As a result, even a pitch between adjacent two holes 110a is very fine (for example, 10 nanometers to 50 nanometers), the flowable metal layer material 120M still can fill up the entirety of such holes 110a.

As illustrated in FIG. 16C, the covering layer CM over the metal layer material 120M is formed by using, for example, deposition, such as ALD, PVD, CVD, etc. After the metal layer material 120M is solidified, the metal layer material 120M has at least one recess 120Mr. The covering layer CM may fill up the recess 120Mr for obtaining a planarized surface in a CMP (Chemical-Mechanical Planarization).

As illustrated in FIG. 16D, the hard mask HM, the covering layer CM, a portion of the metal layer material 120M and a portion of the barrier material 115M is removed by using, for example, CMP. The remaining portion of the metal layer material 120M forms the metal layer 120, and the remaining portion of the barrier material 115M forms the lateral portion 115A which is formed on the sidewall of the hole 110a. After CMP, the dielectric layer 110 forms the upper surface 110u, and the metal layer 120 forms the upper surface 120Au, wherein the upper surface 110u and the upper surface 120Au are aligned with (for example, flushed) each other.

As illustrated in FIG. 16E, at least one capping layer 225 over the metal layer 120 formed by using, deposition, lithography process, etching, etc. In the present embodiment, the capping layer 225 is, for example, a non-reactive capping which does not react with the metal layer 120. The entirety of the capping layer 225 may protrudes relative to an upper surface 110u of the dielectric layer 110. Alternatively, a portion of the capping layer 225 is embedded in the metal layer 120.

As illustrated in FIG. 16F, the etching stop layer 127 over the dielectric layer 110 and the metal layer 120 is formed to form the semiconductor structure 200 by using, for example, deposition, such as ALD, PVD, CVD, etc. Due to the capping layer 225 over the metal layer 120, the etching stop layer 127 does not react with the metal layer 120.

In another embodiment, another dielectric layer 110, another lateral portion 115A (or barrier layer 215), another metal layer 120 and another capping layer 225 (selectively) may be formed on the etching stop layer 127 by using the processes the same as or similar to that of the aforementioned dielectric layer 110, the lateral portion 115A, the metal layer 120 and the capping layer 225. In another embodiment, if not necessary, the etching stop layer 127 in FIG. 16F may be omitted.

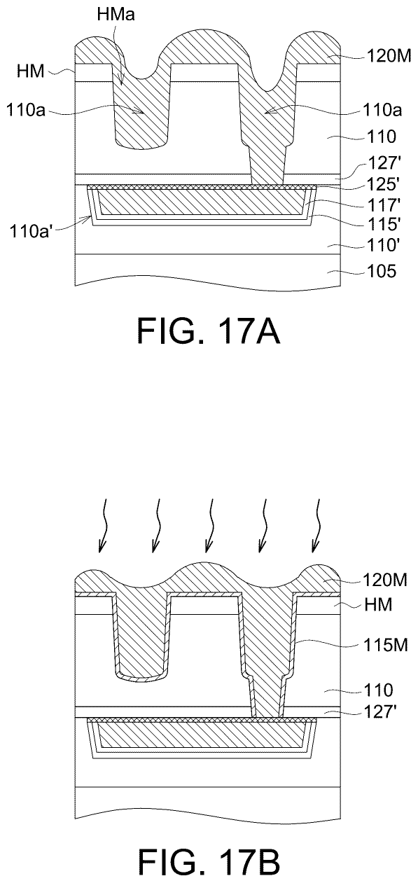

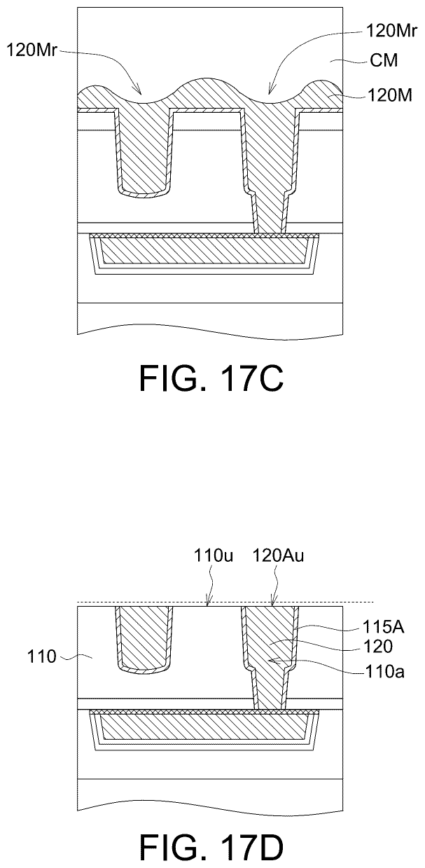

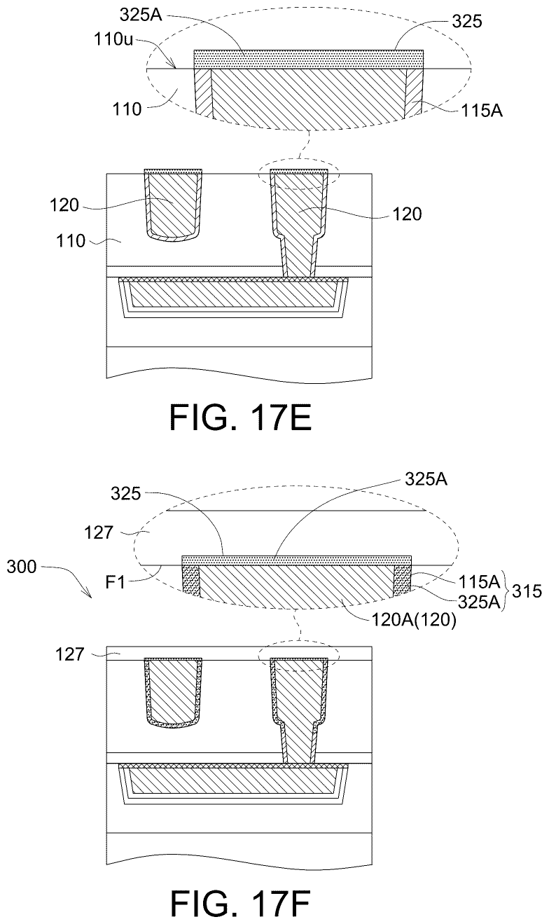

Referring to FIGS. 17A to 17F, FIGS. 17A to 17F illustrate schematic diagrams of manufacturing processes of the semiconductor structure 300 in FIG. 3.

As illustrated in FIG. 17A, the dielectric layer 110′, the barrier layer 115′, the liner 117′, the metal layer 120′, the capping layer 125′ and the etching stop layer 127′ are formed on the substrate 105′. The dielectric layer 110′ has at least one hole 110a′, and the barrier layer 115′, the liner 117′ and the metal layer 120′ are formed within the hole 110a′, wherein the liner 117′ is formed between the barrier layer 115′ and the metal layer 120′. The liner 117′ may be formed by CVD (Chemical Vapor Deposition), ALD (Atomic Layer Deposition), PVD (Physical Vapor Deposition) and/or wet coating process. The liner 117′ may be formed of a material including a metal (for example, Co) and/or an alloy (for example, CoW, CoZrTa). The barrier layer 115′ may be formed by ALD, CVD, PVD and/or wet coating process. The barrier layer 115′ the may be formed of a material including a metal nitride (for example, TaN), a metal oxide (for example, TiOx) and/or alloy (for example, CoNb). The capping layer 125′ is disposed over the metal layer 120′. The etching stop layer 127′ is disposed over the dielectric layer 110′ and the capping layer 125′. The etching stop layer 127′ has at least one opening 127a′, and the metal layer 120 extends to the capping layer 125′ through the opening 127a′.

In FIG. 17A, the dielectric layer 110 is formed over the etching stop layer 127′ by using, for example, deposition, etc. Then, a patterned hard mask HM having at least one opening HMa is formed on the dielectric layer 110′ Then, the dielectric layer 110 is patterned to form at least one hole 110a through the opening HMa by using, for example, etching, etc. One or some of the holes 110a is blind hole, and/or another or some of the holes 110a is through hole which passes through the etching stop layer 127′ and extends to the capping layer 125′. Then, the metal layer material 120M over the hard mask HM is formed by using, for example, deposition, such as CVD, PVD, ALD, etc.

As illustrated in FIG. 17B, the metal layer material 120M is treated by a post treatment that drive metal the metal layer material 120M to be self-formed between itself and the dielectric layer 110. Furthermore, the metal layer material 120M may be heated to a temperature ranging between, for example, room temperature and 100° C. (for example, 300° C. to 400° C.) to form the barrier material 115M. The barrier material 115M is formed on an interface between the dielectric layer 110 and the metal layer material 120M, an interface between the hard mask HM and the metal layer material 120M and an interface between the etching stop layer 127 and the metal layer material 120M. After being heated, the metal layer material 120M becomes flowable and fills up the entirety of the holes 110a. As a result, even a pitch between adjacent two holes 110a is very fine (for example, 10 nanometers to 50 nanometers), the flowable metal layer material 120M still can fill up the entirety of such holes 110a.

As illustrated in FIG. 17C, the covering layer CM over the metal layer material 120M is formed by using, for example, deposition, such as ALD, PVD, CVD, etc. After the metal layer material 120M is solidified, the metal layer material 120M has at least one recess 120Mr. The covering layer CM may fill up the recess 120Mr for obtaining a planarized surface in a CMP (Chemical-Mechanical Planarization).

As illustrated in FIG. 17D, the hard mask HM, the covering layer CM, a portion of the metal layer material 120M and a portion of the barrier material 115M is removed by using, for example, CMP. The remaining portion of the metal layer material 120M forms the metal layer 120, and the remaining portion of the barrier material 115M forms the lateral portion 115A which is formed on the sidewall of the hole 110a. After CMP, the dielectric layer 110 forms the upper surface 110u, and the metal layer 120 forms the upper surface 120Au, wherein the upper surface 110u and the upper surface 120Au are aligned with (for example, flushed) each other.

As illustrated in FIG. 17E, at least one capping layer 325 over the metal layer 120 formed by using, deposition, lithography process, etching, etc. In the present embodiment, the capping layer 325 is, for example, the reactive capping which may react with the metal layer 120. The entirety of the capping layer 325 may protrudes relative to the upper surface 110u of the dielectric layer 110. Alternatively, a portion of the capping layer 325 is embedded in the metal layer 120.

As illustrated in FIG. 17F, the etching stop layer 127 over the dielectric layer 110 and the metal layer 120 is formed to form the semiconductor structure 300 by using, for example, deposition, such as ALD, PVD, CVD, etc. The elements 325A of the capping layer 325 may be diffused into the lateral portion 115A to form the barrier layer 315 by thermal treatment. In the present embodiment, the capping layer 325 may not react with the etching stop layer 127 and the metal layer 120. In the present embodiment, the elements 325A of the capping layer 325 is not fully diffused into the lateral portion 115A, and thus a remaining portion of the capping layer 325 in FIG. 17E is still located at the semiconductor structure. In another embodiment, the elements 325A of the capping layer 325 may be fully diffused into the lateral portion 115A, and the capping layer 325 will be exhausted and does not appear on the semiconductor structure. In addition, the elements 325A in the lateral portion 115A are dispersedly distributed within the lateral portion 115A.

In another embodiment, another dielectric layer 110, another barrier layer 315, another metal layer 120 and t another capping layer 325 (selectively) may be formed on the etching stop layer 127 by using the processes the same as or similar to that of the aforementioned dielectric layer 110, the barrier layer 315, the metal layer 120 and the capping layer 325. In another embodiment, if not necessary, the etching stop layer 127 in FIG. 17F may be omitted.

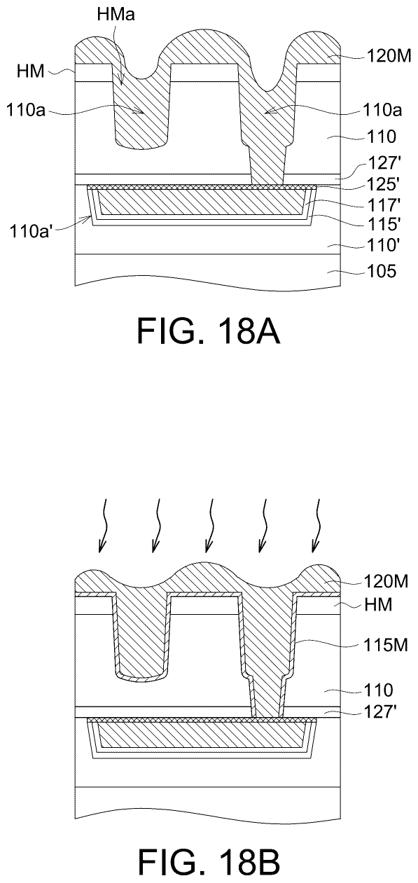

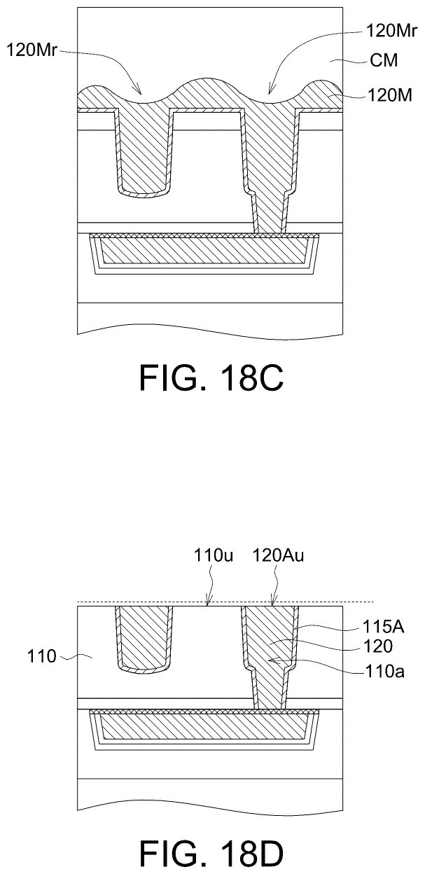

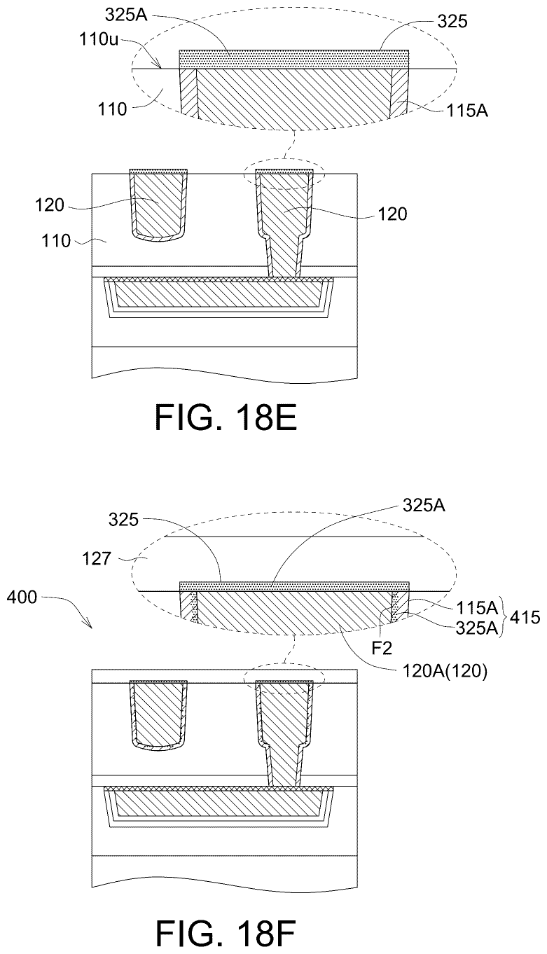

Referring to FIGS. 18A to 18F, FIGS. 18A to 18F illustrate schematic diagrams of manufacturing processes of the semiconductor structure 400 in FIG. 4.

As illustrated in FIG. 18A, the dielectric layer 110′, the barrier layer 115′, the liner 117′, the metal layer 120′, the capping layer 125′ and the etching stop layer 127′ are formed on the substrate 105′. The dielectric layer 110′ has at least one hole 110a′, and the barrier layer 115′, the liner 117′ and the metal layer 120′ are formed within the hole 110a′, wherein the liner 117′ is formed between the barrier layer 115′ and the metal layer 120′. The liner 117′ may be formed by CVD (Chemical Vapor Deposition), ALD (Atomic Layer Deposition), PVD (Physical Vapor Deposition) and/or wet coating process. The liner 117′ may be formed of a material including a metal (for example, Co) and/or an alloy (for example, CoW, CoZrTa). The barrier layer 115′ may be formed by ALD, CVD, PVD and/or wet coating process. The barrier layer 115′ the may be formed of a material including a metal nitride (for example, TaN), a metal oxide (for example, TiOx) and/or alloy (for example, CoNb). The capping layer 125′ is disposed over the metal layer 120′. The etching stop layer 127′ is disposed over the dielectric layer 110′ and the capping layer 125′. The etching stop layer 127′ has at least one opening 127a′, and the metal layer 120 extends to the capping layer 125′ through the opening 127a′.

In FIG. 18A, the dielectric layer 110 is formed over the etching stop layer 127′ by using, for example, deposition, etc. Then, a patterned hard mask HM having at least one opening HMa is formed on the dielectric layer 110. Then, the dielectric layer 110 is patterned to form at least one hole 110a through the opening HMa by using, for example, etching, etc. One or some of the holes 110a is blind hole, and/or another or some of the holes 110a is through hole which passes through the etching stop layer 127′ and extends to the capping layer 125′. Then, the metal layer material 120M over the hard mask HM is formed by using, for example, deposition, such as CVD, PVD, ALD, etc.

As illustrated in FIG. 18B, the metal layer material 120M is treated by a post treatment that drive metal the metal layer material 120M to be self-formed between itself and the dielectric layer 110. Furthermore, the metal layer material 120M may be heated to a temperature ranging between, for example, room temperature and 1000° C. (for example, 300° C. to 400° C.) to form the barrier material 115M. The barrier material 115M is formed on an interface between the dielectric layer 110 and the metal layer material 120M, an interface between the hard mask HM and the metal layer material 120M and an interface between the etching stop layer 127 and the metal layer material 120M. After being heated, the metal layer material 120M becomes flowable and fills up the entirety of the holes 110a. As a result, even a pitch between adjacent two holes 110a is very fine (for example, 10 nanometers to 50 nanometers), the flowable metal layer material 120M still can fill up the entirety of such holes 110a.

As illustrated in FIG. 18C, the covering layer CM over the metal layer material 120M is formed by using, for example, deposition, such as ALD, PVD, CVD, etc. After the metal layer material 120M is solidified, the metal layer material 120M has at least one recess 120Mr. The covering layer CM may fill up the recess 120Mr for obtaining a planarized surface in a CMP (Chemical-Mechanical Planarization).

As illustrated in FIG. 18D, the hard mask HM, the covering layer CM, a portion of the metal layer material 120M and a portion of the barrier material 115M is removed by using, for example, CMP. The remaining portion of the metal layer material 120M forms the metal layer 120, and the remaining portion of the barrier material 115M forms the lateral portion 115A which is formed on the sidewall of the hole 110a. After CMP, the dielectric layer 110 forms the upper surface 110u, and the metal layer 120 forms the upper surface 120Au, wherein the upper surface 110u and the upper surface 120Au are aligned with (for example, flushed) each other.

As illustrated in FIG. 18E, at least one capping layer 325 over the metal layer 120 formed by using, deposition, lithography process, etching, etc. In the present embodiment, the capping layer 325 is, for example, the reactive capping which may react with the metal layer 120. The entirety of the capping layer 325 may protrudes relative to the upper surface 110u of the dielectric layer 110. Alternatively, a portion of the capping layer 325 is embedded in the metal layer 120.

As illustrated in FIG. 18F, the etching stop layer 127 over the dielectric layer 110 and the metal layer 120 is formed to form the semiconductor structure 400 by using, for example, deposition, such as ALD, PVD, CVD, etc. The elements 325A of the capping layer 325 may be diffused into the lateral portion 115A to form the barrier layer 415 by thermal treatment. In the present embodiment, the capping layer 325 may not react with the etching stop layer 127 and the metal layer 120. In the present embodiment, the elements 325A of the capping layer 325 is not fully diffused into the lateral portion 115A, and thus a remaining portion of the capping layer 325 in FIG. 18E is still located at the semiconductor structure. In another embodiment, the elements 325A of the capping layer 325 may be fully diffused into the lateral portion 115A, and the capping layer 325 will be exhausted and does not appear on the semiconductor structure. In addition, compared to the barrier layer 315 in FIG. 17F, the elements 325A in the lateral portion 115A of FIG. 18F are concentrated adjacent to the interface F2 between the lateral portion 115A and the metal layer 120.

In another embodiment, another dielectric layer 110, another barrier layer 415, another metal layer 120 and t another capping layer 325 (selectively) may be formed on the etching stop layer 127 by using the processes the same as or similar to that of the aforementioned dielectric layer 110, the barrier layer 415, the metal layer 120 and the capping layer 325. In another embodiment, if not necessary, the etching stop layer 127 in FIG. 18F may be omitted.

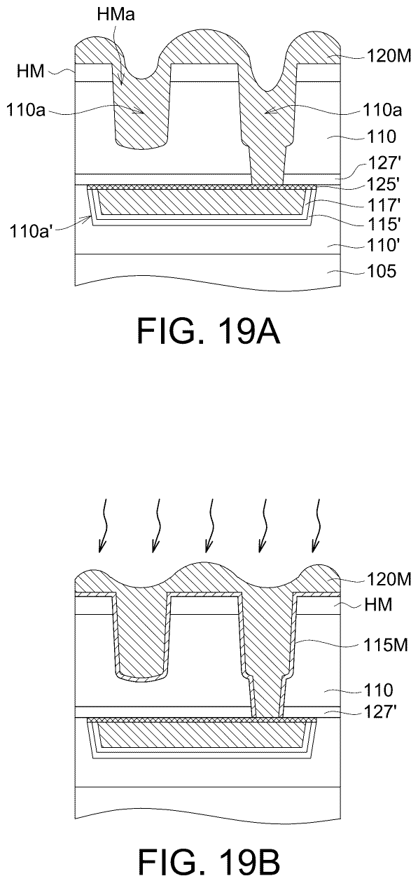

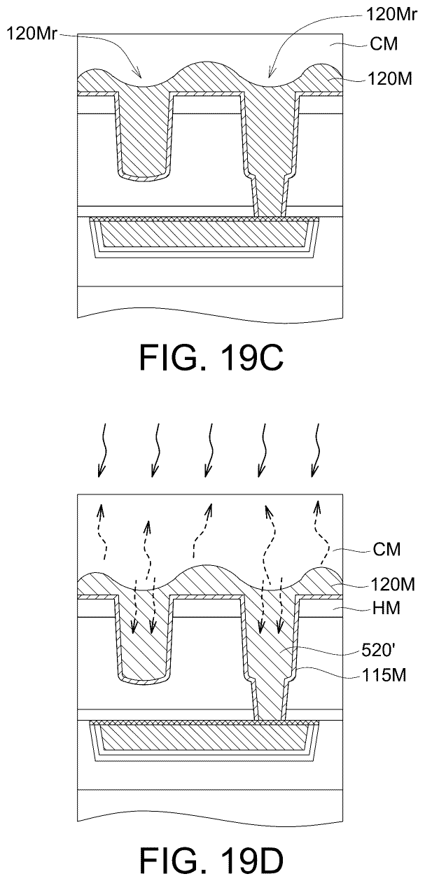

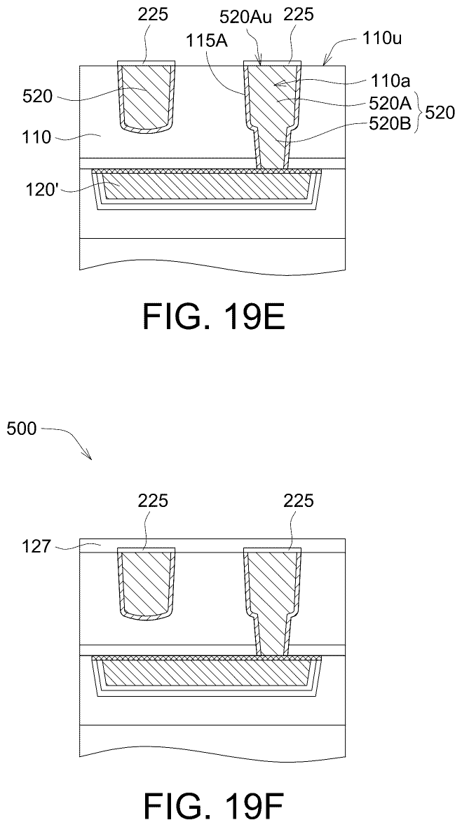

Referring to FIGS. 19A to 19F, FIGS. 19A to 19F illustrate schematic diagrams of manufacturing processes of the semiconductor structure 500 in FIG. 5.

As illustrated in FIG. 19A, the dielectric layer 110′, the barrier layer 115′, the liner 117′, the metal layer 120′, the capping layer 125′ and the etching stop layer 127′ are formed on the substrate 105′. The dielectric layer 110′ has at least one hole 110a′, and the barrier layer 115′, the liner 117′ and the metal layer 120′ are formed within the hole 110a′, wherein the liner 117′ is formed between the barrier layer 115′ and the metal layer 120′. The liner 117′ may be formed by CVD (Chemical Vapor Deposition), ALD (Atomic Layer Deposition), PVD (Physical Vapor Deposition) and/or wet coating process. The liner 117′ may be formed of a material including a metal (for example, Co) and/or an alloy (for example, CoW, CoZrTa). The barrier layer 115′ may be formed by ALD, CVD, PVD and/or wet coating process. The barrier layer 115′ the may be formed of a material including a metal nitride (for example, TaN), a metal oxide (for example, TiOx) and/or alloy (for example, CoNb). The capping layer 125′ is disposed over the metal layer 120′. The etching stop layer 127′ is disposed over the dielectric layer 110′ and the capping layer 125′. The etching stop layer 127′ has at least one opening 127a′, and the metal layer 120 extends to the capping layer 125′ through the opening 127a′.

In FIG. 19A, the dielectric layer 110 is formed over the etching stop layer 127′ by using, for example, deposition, etc. Then, a patterned hard mask HM having at least one opening HMa is formed on the dielectric layer 110. Then, the dielectric layer 110 is patterned to form at least one hole 110a through the opening HMa by using, for example, etching, etc. One or some of the holes 110a is blind hole, and/or another or some of the holes 110a is through hole which passes through the etching stop layer 127′ and extends to the capping layer 125′. Then, the metal layer material 120M over the hard mask HM is formed by using, for example, deposition, such as CVD, PVD, ALD, etc.

As illustrated in FIG. 19B, the metal layer material 120M is treated by a post treatment that drive metal the metal layer material 120M to be self-formed between itself and the dielectric layer 110. Furthermore, the metal layer material 120M may be heated to a temperature ranging between, for example, room temperature and 1000° C. (for example, 300° C. to 400° C.) to form the barrier material 115M. The barrier material 115M is formed on an interface between the dielectric layer 110 and the metal layer material 120M, an interface between the hard mask HM and the metal layer material 120M and an interface between the etching stop layer 127 and the metal layer material 120M. After being heated, the metal layer material 120M becomes flowable and fills up the entirety of the holes 110a. As a result, even a pitch between adjacent two holes 110a is very fine (for example, 10 nanometers to 50 nanometers), the flowable metal layer material 120M still can fill up the entirety of such holes 110a.

As illustrated in FIG. 19C, the covering layer CM over the metal layer material 120M is formed by using, for example, deposition, such as ALD, PVD, CVD, etc. After the metal layer material 120M is solidified, the metal layer material 120M has at least one recess 120Mr. The covering layer CM may fill up the recess 120Mr for obtaining a planarized surface in a CMP (Chemical-Mechanical Planarization).

In FIG. 19C, the covering layer CM is formed of a first chemical element, and the metal layer material 120M is formed of the first chemical element and a second chemical element, wherein the first chemical element is, for example, Cu, and the second chemical element is, for example, Al or the element other than the first chemical element. In an embodiment, the covering layer CM has 100% of the first chemical element, while the concentration of the first chemical element in the metal layer material 120M is less than 100%, and equal to, greater than or less than the concentration of the second chemical element in the metal layer material 120M.

As illustrated in FIG 19D, the covering layer CM and the metal layer material 120M are heated to a temperature ranging between, for example, room temperature and 1000° C. (for example, 300° C. to 400° C.) to form the metal layer 520′. The first chemical element of the metal layer 520′ has the concentration different from that of the first chemical element of the metal layer material 120M. For example, the metal layer 520′ includes the first chemical element and the second chemical element, wherein the concentration of the first chemical element of the metal layer 520′ is greater than that of the first chemical element of the metal layer material 120M, and the concentration of the second chemical element of the metal layer 520′ is less than that of the second chemical element of the metal layer material 120M. In other words, during the heating for the covering layer CM and the metal layer material 120M, the first chemical element of the covering layer CM may diffuse into the metal layer material 120M to increase the concentration of the first chemical element in the metal layer material 120M, and the second chemical element of the metal layer material 120M may diffuse into the covering layer CM to increase the concentration of the second chemical element in the covering layer CM.

As illustrated in FIG. 19E, the hard mask HM, the covering layer CM, a portion of the metal layer 520′ and a portion of the barrier material 115M is removed by using, for example, CMP. The remaining portion of the metal layer 520′ forms the metal layer 520, and the remaining portion of the barrier material 115M forms the lateral portion 115A which is formed on the sidewall of the hole 110a. After CMP, the dielectric layer 110 forms the upper surface 110u, and the metal layer 520 forms the upper surface 520Au, wherein the upper surface 110u and the upper surface 520Au are aligned with (for example, flushed) each other. The metal layers 520 includes the trace portion 520A and the via portion 520B, wherein the via portion 520B connects the trace portion 520A with the metal layer 120′. Then, at least one capping layer 225 over the metal layer 520 formed by using, deposition, lithography process, etching, etc. In the present embodiment, the capping layer 225 is, for example, a non-reactive capping which does not react with the metal layer 520. The entirety of the capping layer 225 may protrudes relative to an upper surface 110u of the dielectric layer 110. Alternatively, a portion of the capping layer 225 is embedded in the metal layer 520.

As illustrated in FIG. 19F, the etching stop layer 127 over the dielectric layer 110 and the metal layer 520 is formed to form the semiconductor structure 500 by using, for example, deposition, such as ALD, PVD, CVD, etc. Due to the capping layer 225 over the metal layer 120, the etching stop layer 127 does not react with the metal layer 520.

In another embodiment, another dielectric layer 110, another barrier layer 115A (or another barrier layer 225), another metal layer 520 and t another capping layer 225 (selectively) may be formed on the etching stop layer 127 by using the processes the same as or similar to that of the aforementioned dielectric layer 110, the barrier layer 115A (or another barrier layer 225), the metal layer 520 and the capping layer 225. In another embodiment, if not necessary, the etching stop layer 127 in FIG. 19F may be omitted.

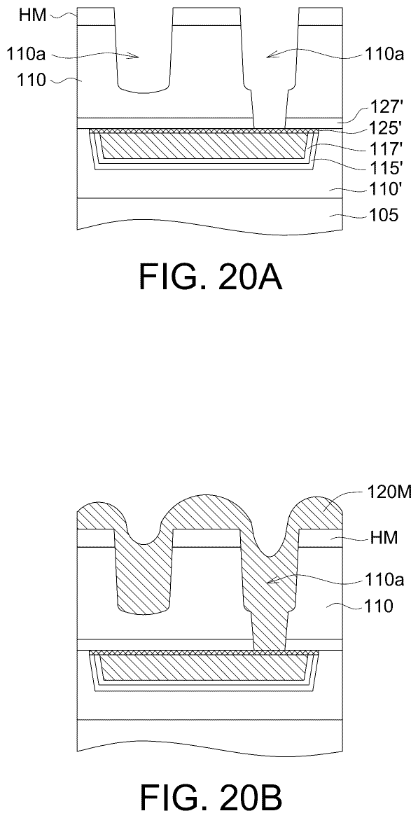

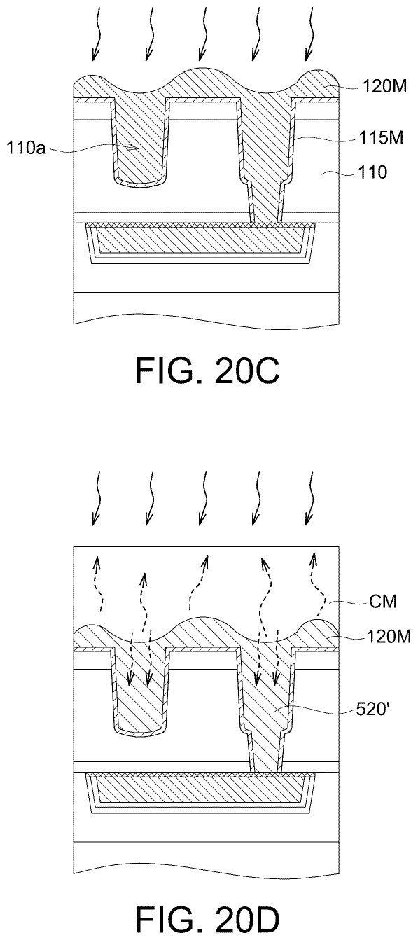

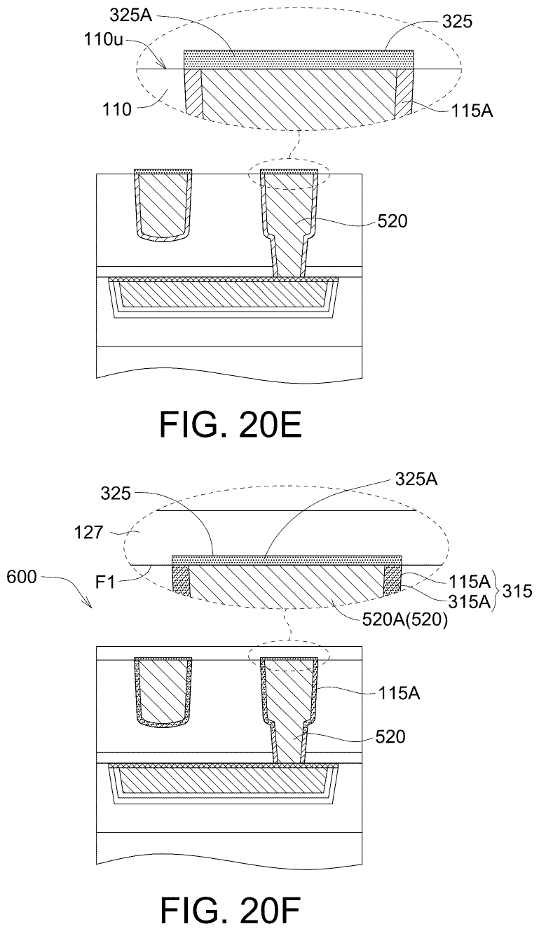

Referring to FIGS. 20a to 20f, FIGS. 20a to 20f illustrate schematic diagrams of manufacturing processes of the semiconductor structure 600 in FIG. 6.

As illustrated in FIG. 20A, the dielectric layer 110′, the barrier layer 115′, the liner 117′, the metal layer 120′, the capping layer 125′ and the etching stop layer 127′ are formed on the substrate 105′. The dielectric layer 110′ has at least one hole 110a′, and the barrier layer 115′, the liner 117′ and the metal layer 120′ are formed within the hole 110a′, wherein the liner 117′ is formed between the barrier layer 115′ and the metal layer 120′. The liner 117′ may be formed by CVD (Chemical Vapor Deposition), ALD (Atomic Layer Deposition), PVD (Physical Vapor Deposition) and/or wet coating process. The liner 117′ may be formed of a material including a metal (for example, Co) and/or an alloy (for example, CoW, CoZrTa). The barrier layer 115′ may be formed by ALD, CVD, PVD and/or wet coating process. The barrier layer 115′ the may be formed of a material including a metal nitride (for example, TaN), a metal oxide (for example, TiOx) and/or alloy (for example, CoNb). The capping layer 125′ is disposed over the metal layer 120′. The etching stop layer 127′ is disposed over the dielectric layer 110′ and the capping layer 125′. The etching stop layer 127′ has at least one opening 127a′, and the metal layer 120 extends to the capping layer 125′ through the opening 127a′.

In FIG. 20A, the dielectric layer 110 is formed over the etching stop layer 127′ by using, for example, deposition, etc. Then, a patterned hard mask HM having at least one opening HMa is formed on the dielectric layer 110. Then, the dielectric layer 110 is patterned to form at least one hole 110a through the opening HMa by using, for example, etching, etc. One or some of the holes 110a is blind hole, and/or another or some of the holes 110a is through hole which passes through the etching stop layer 127′ and extends to the capping layer 125′.

As illustrated in FIG. 20B, the metal layer material 120M over the hard mask HM is formed by using, for example, deposition, such as CVD, PVD, ALD, etc.

As illustrated in FIG. 20C, the metal layer material 120M is treated by a post treatment that drive metal the metal layer material 120M to be self-formed between itself and the dielectric layer 110. Furthermore, the metal layer material 120M may be heated to a temperature ranging between, for example, room temperature and 1000° C. (for example, 300° C. to 400° C.) to form the barrier material 115M. The barrier material 115M is formed on an interface between the dielectric layer 110 and the metal layer material 120M, an interface between the hard mask HM and the metal layer material 120M and an interface between the etching stop layer 127 and the metal layer material 120M. After being heated, the metal layer material 120M becomes flowable and fills up the entirety of the holes 110a. As a result, even a pitch between adjacent two holes 110a is very fine (for example, 10 nanometers to 50 nanometers), the flowable metal layer material 120M still can fill up the entirety of such holes 110a.

As illustrated in FIG. 20D, the covering layer CM over the metal layer material 120M is formed by using, for example, deposition, such as ALD, PVD, CVD, etc. After the metal layer material 120M is solidified, the metal layer material 120M has at least one recess 120Mr. The covering layer CM may fill up the recess 120Mr for obtaining a planarized surface in a CMP (Chemical-Mechanical Planarization).

In FIG. 20D, the covering layer CM is formed of a first chemical element, and the metal layer material 120M is formed of the first chemical element and a second chemical element, wherein the first chemical element is, for example, Cu, and the second chemical element is, for example, Al or the element other than the first chemical element. In an embodiment, the covering layer CM has 100% of the first chemical element, while the concentration of the first chemical element in the metal layer material 120M is less than 100%, and equal to, greater than or less than the concentration of the second chemical element in the metal layer material 120M. Then, the covering layer CM and the metal layer material 120M are heated to a temperature ranging between, for example, room temperature and 1000° C. (for example, 300° C. to 400° C.) to form the metal layer 520′. The first chemical element of the metal layer 520′ has the concentration different from that of the first chemical element of the metal layer material 120M. For example, the metal layer 520′ includes the first chemical element and the second chemical element, wherein the concentration of the first chemical element of the metal layer 520′ is greater than that of the first chemical element of the metal layer material 120M, and the concentration of the second chemical element of the metal layer 520′ is less than that of the second chemical element of the metal layer material 120M. In other words, during the heating for the covering layer CM and the metal layer material 120M, the first chemical element of the covering layer CM may diffuse into the metal layer material 120M to increase the concentration of the first chemical element in the metal layer material 120M, and the second chemical element of the metal layer material 120M may diffuse into the covering layer CM to increase the concentration of the second chemical element in the covering layer CM.

As illustrated in FIG. 20E, the hard mask HM, the covering layer CM, a portion of the metal layer 520′ and a portion of the barrier material 115M is removed by using, for example, CMP. The remaining portion of the metal layer 520′ forms the metal layer 520, and the remaining portion of the barrier material 115M forms the lateral portion 115A which is formed on the sidewall of the hole 110a. After CMP, the dielectric layer 110 forms the upper surface 110u, and the metal layer 520 forms the upper surface 520Au, wherein the upper surface 110u and the upper surface 520Au are aligned with (for example, flushed) each other. The metal layers 520 includes the trace portion 520A and the via portion 520B, wherein the via portion 520B connects the trace portion 520A with the metal layer 120′. Then, at least one capping layer 325 over the metal layer 520 formed by using, deposition, lithography process, etching, etc. In the present embodiment, the capping layer 325 is, for example, the reactive capping which may react with the metal layer 520. The entirety of the capping layer 325 may protrudes relative to the upper surface 110u of the dielectric layer 110. Alternatively, a portion of the capping layer 325 is embedded in the metal layer 520.

As illustrated in FIG. 20F, the etching stop layer 127 over the dielectric layer 110 and the metal layer 520 is formed to form the semiconductor structure 600 by using, for example, deposition, such as ALD, PVD, CVD, etc. The elements 325A of the capping layer 325 may be diffused into the lateral portion 115A to form the barrier layer 315 by thermal treatment. In the present embodiment, the capping layer 325 may not react with the etching stop layer 127 and the metal layer 520. In the present embodiment, the elements 325A of the capping layer 325 is not fully diffused into the lateral portion 115A, and thus a remaining portion of the capping layer 325 in FIG. 20E is still located at the semiconductor structure. In another embodiment, the elements 325A of the capping layer 325 may be fully diffused into the lateral portion 115A, and the capping layer 325 will be exhausted and does not appear on the semiconductor structure. In addition, the elements 325A in the lateral portion 115A are dispersedly distributed within the lateral portion 115A.

In another embodiment, another dielectric layer 110, another barrier layer 315, another metal layer 520 and t another capping layer 325 (selectively) may be formed on the etching stop layer 127 by using the processes the same as or similar to that of the aforementioned dielectric layer 110, the barrier layer 315, the metal layer 520 and the capping layer 325. In another embodiment, if not necessary, the etching stop layer 127 in FIG. 20F may be omitted.

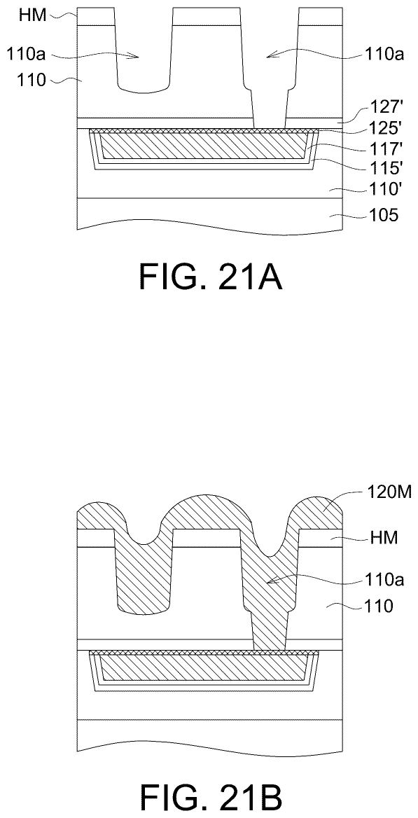

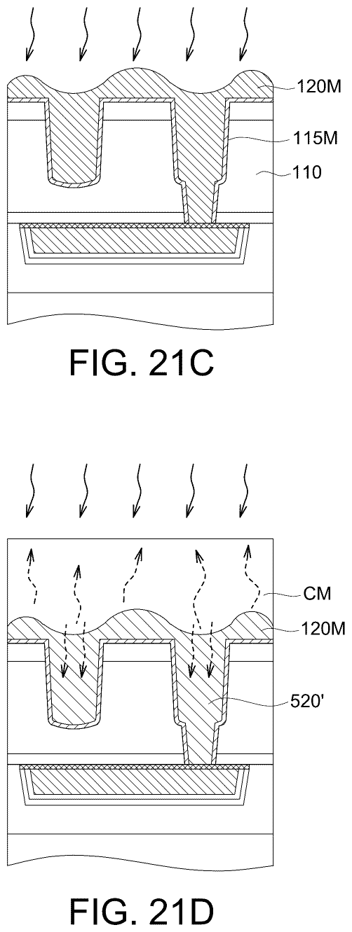

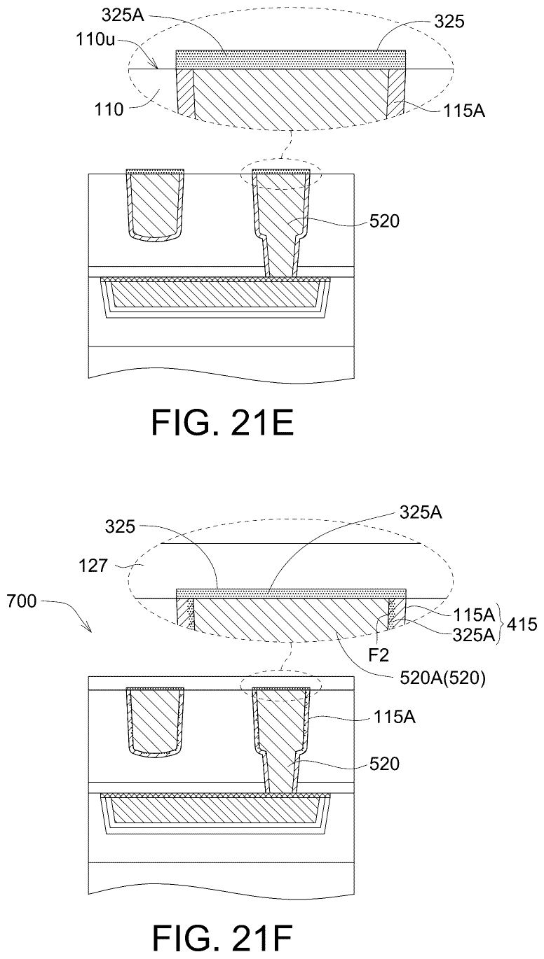

Referring to FIGS. 21A to 21F, FIGS. 21A to 21F illustrate schematic diagrams of manufacturing processes of the semiconductor structure 700 in FIG. 7.

As illustrated in FIG. 21A, the dielectric layer 110′, the barrier layer 115′, the liner 117′, the metal layer 120′, the capping layer 125′ and the etching stop layer 127′ are formed on the substrate 105′. The dielectric layer 110′ has at least one hole 110a′, and the barrier layer 115′, the liner 117′ and the metal layer 120′ are formed within the hole 110a′, wherein the liner 117′ is formed between the barrier layer 115′ and the metal layer 120′. The liner 117′ may be formed by CVD (Chemical Vapor Deposition), ALD (Atomic Layer Deposition), PVD (Physical Vapor Deposition) and/or wet coating process. The liner 117′ may be formed of a material including a metal (for example, Co) and/or an alloy (for example, CoW, CoZrTa). The barrier layer 115′ may be formed by ALD, CVD, PVD and/or wet coating process. The barrier layer 115′ the may be formed of a material including a metal nitride (for example, TaN), a metal oxide (for example, TiOx) and/or alloy (for example, CoNb). The capping layer 125′ is disposed over the metal layer 120′. The etching stop layer 127′ is disposed over the dielectric layer 110′ and the capping layer 125′. The etching stop layer 127′ has at least one opening 127a′, and the metal layer 120 extends to the capping layer 125′ through the opening 127a′.

In FIG. 21A, the dielectric layer 110 is formed over the etching stop layer 127′ by using, for example, deposition, etc. Then, a patterned hard mask HM having at least one opening HMa is formed on the dielectric layer 110. Then, the dielectric layer 110 is patterned to form at least one hole 110a through the opening HMa by using, for example, etching, etc. One or some of the holes 110a is blind hole, and/or another or some of the holes 110a is through hole which passes through the etching stop layer 127′ and extends to the capping layer 125′.

As illustrated in FIG. 21B, the metal layer material 120M over the hard mask HM is formed by using, for example, deposition, such as CVD, PVD, ALD, etc.

As illustrated in FIG. 21C, the metal layer material 120M is treated by a post treatment that drive metal the metal layer material 120M to be self-formed between itself and the dielectric layer 110. Furthermore, the metal layer material 120M may be heated to a temperature ranging between, for example, room temperature and 1000° C. (for example, 300° C. to 400° C.) to form the barrier material 115M. The barrier material 115M is formed on an interface between the dielectric layer 110 and the metal layer material 120M, an interface between the hard mask HM and the metal layer material 120M and an interface between the etching stop layer 127 and the metal layer material 120M. After being heated, the metal layer material 120M becomes flowable and fills up the entirety of the holes 110a. As a result, even a pitch between adjacent two holes 110a is very fine (for example, 10 nanometers to 50 nanometers), the flowable metal layer material 120M still can fill up the entirety of such holes 110a.

As illustrated in FIG. 21D, the covering layer CM over the metal layer material 120M is formed by using, for example, deposition, such as ALD, PVD, CVD, etc. After the metal layer material 120M is solidified, the metal layer material 120M has at least one recess 120Mr. The covering layer CM may fill up the recess 120Mr for obtaining a planarized surface in a CMP (Chemical-Mechanical Planarization).

In FIG. 21D, the covering layer CM is formed of a first chemical element, and the metal layer material 120M is formed of the first chemical element and a second chemical element, wherein the first chemical element is, for example, Cu, and the second chemical element is, for example, Al or the element other than the first chemical element. In an embodiment, the covering layer CM has 100% of the first chemical element, while the concentration of the first chemical element in the metal layer material 120M is less than 100%, and equal to, greater than or less than the concentration of the second chemical element in the metal layer material 120M. Then, the covering layer CM and the metal layer material 120M are heated to a temperature ranging between, for example, room temperature and 1000° C. (for example, 300° C. to 400° C.) to form the metal layer 520′. The first chemical element of the metal layer 520′ has the concentration different from that of the first chemical element of the metal layer material 120M. For example, the metal layer 520′ includes the first chemical element and the second chemical element, wherein the concentration of the first chemical element of the metal layer 520′ is greater than that of the first chemical element of the metal layer material 120M, and the concentration of the second chemical element of the metal layer 520′ is less than that of the second chemical element of the metal layer material 120M. In other words, during the heating for the covering layer CM and the metal layer material 120M, the first chemical element of the covering layer CM may diffuse into the metal layer material 120M to increase the concentration of the first chemical element in the metal layer material 120M, and the second chemical element of the metal layer material 120M may diffuse into the covering layer CM to increase the concentration of the second chemical element in the covering layer CM.

As illustrated in FIG. 21E, the hard mask HM, the covering layer CM, a portion of the metal layer 520′ and a portion of the barrier material 115M is removed by using, for example, CMP. The remaining portion of the metal layer 520′ forms the metal layer 520, and the remaining portion of the barrier material 115M forms the lateral portion 115A which is formed on the sidewall of the hole 110a. After CMP, the dielectric layer 110 forms the upper surface 110u, and the metal layer 520 forms the upper surface 520Au, wherein the upper surface 110u and the upper surface 520Au are aligned with (for example, flushed) each other. The metal layers 520 includes the trace portion 520A and the via portion 520B, wherein the via portion 520B connects the trace portion 520A with the metal layer 120′. Then, at least one capping layer 325 over the metal layer 520 formed by using, deposition, lithography process, etching, etc. In the present embodiment, the capping layer 325 is, for example, the reactive capping which may react with the metal layer 520. The entirety of the capping layer 325 may protrudes relative to the upper surface 110u of the dielectric layer 110. Alternatively, a portion of the capping layer 325 is embedded in the metal layer 520.

As illustrated in FIG. 21F, the etching stop layer 127 over the dielectric layer 110 and the metal layer 520 is formed to form the semiconductor structure 700 by using, for example, deposition, such as ALD, PVD, CVD, etc. The elements 325A of the capping layer 325 may be diffused into the lateral portion 115A to form the barrier layer 415 by thermal treatment. In the present embodiment, the capping layer 325 may not react with the etching stop layer 127 and the metal layer 520. In the present embodiment, the elements 325A of the capping layer 325 is not fully diffused into the lateral portion 115A, and thus a remaining portion of the capping layer 325 in FIG. 21F is still located at the semiconductor structure. In another embodiment, the elements 325A of the capping layer 325 may be fully diffused into the lateral portion 115A, and the capping layer 325 will be exhausted and does not appear on the semiconductor structure. In addition, compared to the barrier layer 315 in FIG. 20F, the elements 325A in the lateral portion 115A of FIG. 21F are concentrated adjacent to the interface F2 between the lateral portion 115A and the metal layer 520.

In another embodiment, another dielectric layer 110, another barrier layer 415, another metal layer 520 and t another capping layer 325 (selectively) may be formed on the etching stop layer 127 by using the processes the same as or similar to that of the aforementioned dielectric layer 110, the barrier layer 415, the metal layer 520 and the capping layer 325. In another embodiment, if not necessary, the etching stop layer 127 in FIG. 21F may be omitted.

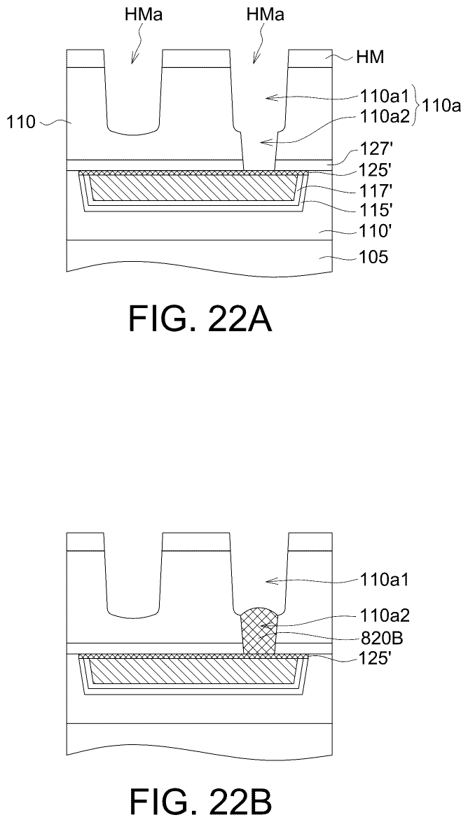

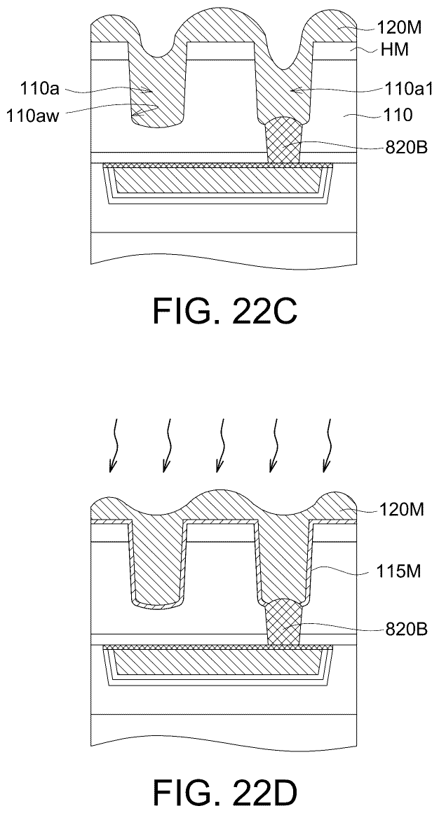

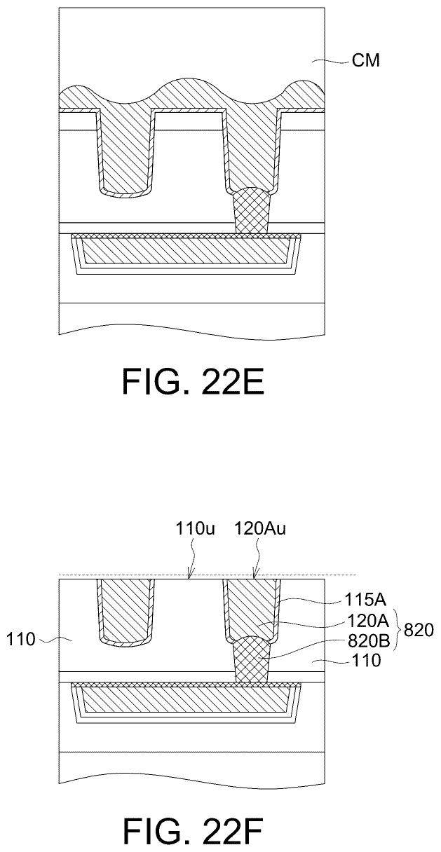

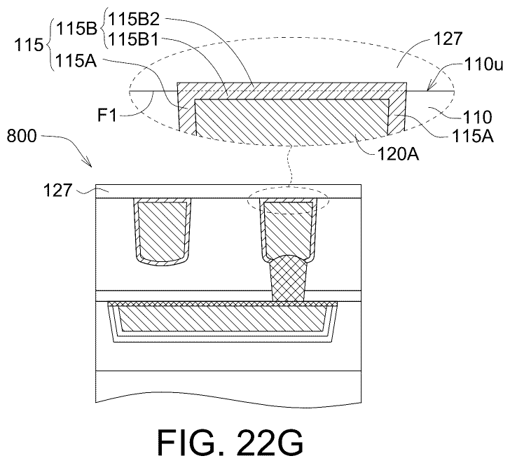

Referring to FIGS. 22A to 22F, FIGS. 22A to 22F illustrate schematic diagrams of manufacturing processes of the semiconductor structure 800 in FIG. 8.

As illustrated in FIG. 22A, the dielectric layer 110′, the barrier layer 115′, the liner 117′, the metal layer 120′, the capping layer 125′ and the etching stop layer 127′ are formed on the substrate 105′. The dielectric layer 110′ has at least one hole 110a′, and the barrier layer 115′, the liner 117′ and the metal layer 120′ are formed within the hole 110a′, wherein the liner 117′ is formed between the barrier layer 115′ and the metal layer 120′. The liner 117′ may be formed by CVD (Chemical Vapor Deposition), ALD (Atomic Layer Deposition), PVD (Physical Vapor Deposition) and/or wet coating process. The liner 117′ may be formed of a material including a metal (for example, Co) and/or an alloy (for example, CoW, CoZrTa). The barrier layer 115′ may be formed by ALD, CVD, PVD and/or wet coating process. The barrier layer 115′ the may be formed of a material including a metal nitride (for example, TaN), a metal oxide (for example, TiOx) and/or alloy (for example, CoNb). The capping layer 125′ is disposed over the metal layer 120′. The etching stop layer 127′ is disposed over the dielectric layer 110′ and the capping layer 125′. The etching stop layer 127′ has at least one opening 127a′, and the metal layer 120 extends to the capping layer 125′ through the opening 127a′.

In FIG. 22A, the dielectric layer 110 is formed over the etching stop layer 127′ by using, for example, deposition, etc. Then, a patterned hard mask HM having at least one opening HMa is formed on the dielectric layer 110. Then, the dielectric layer 110 is patterned to form at least one hole 110a through the opening HMa by using, for example, etching, etc. One or some of the holes 110a is blind hole, and/or another or some of the holes 110a is through hole which passes through the etching stop layer 127′ and extends to the capping layer 125′. In the present embodiment, the hole 110a includes a first hole portion 110a1 and a second hole portion 110a2 connected with the first hole portion 110a1, wherein the second hole portion 110a2 extends to the etching stop layer 127′.

As illustrated in FIG. 22B, the via portion 820B is formed within the second hole portion 110a2. The via portion 820B may be selectively formed from the capping layer 125′ by using, for example, deposition, such as CVD, PVD, ALD, etc. In process of formation of the via portion 820B, the material of the via portion 820B does not react with the dielectric layer 110 and the etching stop layer 127, and thus there is no via portion material formed with the left hole 110a which does not extend to the capping layer 125′. The via portion 820B may be formed of a material including tungsten (W), Ruthenium (Ru), Molybdenum (Mo) or a combination thereof. The via portion 820B is in directly contact with the sidewall of the second hole portion 110a2.

As illustrated in FIG. 22C, the metal layer material 120M over the hard mask HM is formed by using, for example, deposition, such as CVD, PVD, ALD, etc.

As illustrated in FIG. 22D, the metal layer material 120M is treated by a post treatment that drive metal the metal layer material 120M to be self-formed between itself and the dielectric layer 110. Furthermore, the metal layer material 120M may be heated to a temperature ranging between, for example, room temperature and 1000° C. (for example, 300° C. to 400° C.) to form the barrier material 115M. The barrier material 115M is formed on an interface between the dielectric layer 110 and the metal layer material 120M, an interface between the hard mask HM and the metal layer material 120M and an interface between the etching stop layer 127 and the metal layer material 120M. After being heated, the metal layer material 120M becomes flowable and fills up the entirety of the first hole portion 110a1. As a result, even a pitch between adjacent two holes 110a is very fine (for example, 10 nanometers to 50 nanometers), the flowable metal layer material 120M still can fill up the entirety of such holes 110a.

In FIG. 22D, by the thermal driving in the post treatment, the material of the metal layer 120M may diffuse to the dielectric layer 110 through the sidewall 110aw of the hole 110a in FIG. 22C, and the material of the dielectric layer 110 may diffuse to the metal layer 120M through the sidewall 110aw of the hole 110a in FIG. 22C, and the material (or element) of the metal layer 120M and the material (or element) of the dielectric layer 110 chemically react with each other to form the barrier material 115M.

As illustrated in FIG. 22E, the covering layer CM over the metal layer material 120M is formed by using, for example, deposition, such as ALD, PVD, CVD, etc. After the metal layer material 120M is solidified, the metal layer material 120M has at least one recess 120Mr. The covering layer CM may fill up the recess 120Mr for obtaining a planarized surface in a CMP (Chemical-Mechanical Planarization).

As illustrated in FIG. 22F, the hard mask HM, the covering layer CM, a portion of the metal layer 120M and a portion of the barrier material 115M is removed by using, for example, CMP. The remaining portion of the metal layer 120M forms the trace portion 120A, and the remaining portion of the barrier material 115M forms the lateral portion 115A which is formed on the sidewall of the second hole portion 110a2. After CMP, the dielectric layer 110 forms the upper surface 110u, and the trace portion 120A forms the upper surface 120Au, wherein the upper surface 110u and the upper surface 120Au are aligned with (for example, flushed) each other.

As illustrated in FIG. 22G, the etching stop layer 127 over the dielectric layer 110 and the metal layer 820 is formed to form the semiconductor structure 800 by using, for example, deposition, such as ALD, PVD, CVD, etc. The etching stop layer 127 is formed at a temperature, for example, 300° C. to 400° C. to form the upper portion 115B by thermal diffusion. The lateral portion 115A and the upper portion 115B form the barrier layer 115. In other words, the trace portion 120A may react with the etching stop layer 127 to form the upper portion 115B. The upper portion 115B includes the first portion 115B1 and the second portion 115B2, wherein the first portion 115B1 is formed below the interface F1 between the dielectric layer 110 and the etching stop layer 127, and the second portion 115B2 is formed above the interface F1.

In another embodiment, another dielectric layer 110, another barrier layer 115 and another metal layer 820 may be formed on the etching stop layer 127 by using the processes the same as or similar to that of the aforementioned dielectric layer 110, the barrier layer 115 and the metal layer 820. In another embodiment, if not necessary, the etching stop layer 127 in FIG. 22G may be omitted.

The manufacturing method of the semiconductor structure 900 in FIG. 9 includes the steps the same as or similar to that of the semiconductor structure 200 in FIG. 2, and the difference is that the via portion 820B of FIG. 8 is formed in the hole 110a in FIG. 2, wherein the formation of the via portion 820B is the same as or similar to the step in FIG. 22B. The manufacturing method of the semiconductor structure 1000 in FIG. 10 includes the steps the same as or similar to that of the semiconductor structure 300 in FIG. 3, and the difference is that the via portion 820B of FIG. 8 is formed in the hole 110a in FIG. 3, wherein the formation of the via portion 820B is the same as or similar to the step in FIG. 22B. The manufacturing method of the semiconductor structure 1100 in FIG. 11 includes the steps the same as or similar to that of the semiconductor structure 400 in FIG. 4, and the difference is that the via portion 820B of FIG. 8 is formed in the hole 110a in FIG. 4, wherein the formation of the via portion 820B is the same as or similar to the step in FIG. 22B. The manufacturing method of the semiconductor structure 1200 in FIG. 12 includes the steps the same as or similar to that of the semiconductor structure 500 in FIG. 5, and the difference is that the via portion 820B of FIG. 8 is formed in the hole 110a in FIG. 5, wherein the formation of the via portion 820B is the same as or similar to the step in FIG. 22B. The manufacturing method of the semiconductor structure 1300 in FIG. 13 includes the steps the same as or similar to that of the semiconductor structure 600 in FIG. 6, and the difference is that the via portion 820B of FIG. 8 is formed in the hole 110a in FIG. 6, wherein the formation of the via portion 820B is the same as or similar to the step in FIG. 22B. The manufacturing method of the semiconductor structure 1400 in FIG. 14 includes the steps the same as or similar to that of the semiconductor structure 700 in FIG. 7, and the difference is that the via portion 820B of FIG. 8 is formed in the hole 110a in FIG. 7, wherein the formation of the via portion 820B is the same as or similar to the step in FIG. 22B.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor structure includes a substrate, a dielectric layer, a barrier layer and a metal layer. The dielectric layer is disposed on the substrate and has a hole. The barrier layer is disposed within the hole. The metal layer is disposed within the hole and in contact with the barrier layer. In the present embodiment, a liner layer between the metal layer and the barrier layer may be omitted, and thus the volume of the metal layer in the hole may be increased and the conductive quality of the metal layer may be improved.
Example embodiment 1: a semiconductor structure includes a substrate, a dielectric layer, a barrier layer and a metal layer. The dielectric layer is disposed on the substrate and has a hole. The barrier layer is disposed within the hole. The metal layer is disposed within the hole and in contact with the barrier layer.
Example embodiment 2 based on Example embodiment 1: the metal layer has an upper surface, and the semiconductor structure further includes a capping layer over the upper surface of the metal upper surface.
Example embodiment 3 based on Example embodiment 2: the capping layer is non-reactive capping which does not react with the metal layer.
Example embodiment 4 based on Example embodiment 2: the capping layer is reactive capping with the metal layer.
Example embodiment 5 based on Example embodiment 4: the capping layer includes a plurality of chemical elements, the chemical elements are mixed with the barrier layer.
Example embodiment 6 based on Example embodiment 5: the chemical elements are dispersedly distributed within the barrier layer.
Example embodiment 7 based on Example embodiment 5: the chemical elements are concentrated adjacent to an interface between the metal layer and the barrier layer.
Example embodiment 8 based on Example embodiment 1: the metal layer is formed of Cu-based alloy, Co based alloy, Al-based alloy, Ni-based alloy or Ag-based alloy, and the barrier layer is formed of the elements from the metal alloy that formed into the compounds including metal-oxide, metal-nitride, metal-carbide, metal-silicide, and metal-silicate.
Example embodiment 9 based on Example embodiment 1: the barrier layer covers a sidewall of the hole and the metal layer.
Example embodiment 10 based on Example embodiment 1: the semiconductor structure further includes an etching stop layer over the dielectric layer. A portion of the barrier layer is disposed between the etching stop layer and the metal layer.
Example embodiment 11: a semiconductor structure includes a substrate, a dielectric layer, a metal layer and a barrier layer. The dielectric layer is disposed on the substrate and has a hole. The metal layer includes a trace portion and a via portion, wherein the via portion is disposed a lower portion of the hole, the trace portion is disposed an upper portion of the hole, and the trace portion and the via portion are different in material. The barrier layer is disposed between the trace portion and the dielectric layer.
Example embodiment 12 based on Example embodiment 11: the via portion is in directly contact with the dielectric layer.
Example embodiment 13 based on Example embodiment 11: the metal layer has an upper surface, and the semiconductor structure further includes a capping layer over the upper surface of the metal upper surface.
Example embodiment 14 based on Example embodiment 13: the capping layer is non-reactive capping which does not react with the metal layer.
Example embodiment 15 based on Example embodiment 13: the capping layer is reactive capping with the metal layer.
Example embodiment 16 based on Example embodiment 15: the capping layer includes a plurality of chemical elements, the chemical elements are mixed with the barrier layer.
Example embodiment 17: a manufacturing method for a semiconductor structure includes the following steps: forming a dielectric layer on the substrate, wherein the dielectric layer has a hole; forming a metal layer within the hole; and forming a barrier layer within the hole, wherein the metal layer is contact with the barrier layer.
Example embodiment 18 based on Example embodiment 17: forming the metal layer within the hole includes: heating the metal layer to make the metal layer be flowable.
Example embodiment 19 based on Example embodiment 17: forming the barrier layer within the hole includes: forming the barrier layer by heating the metal layer, wherein the barrier layer is disposed between the metal layer and the dielectric layer.
Example embodiment 20 based on Example embodiment 17: manufacturing method further includes: forming a capping layer over an upper surface of the metal layer, wherein the capping layer is a reactive capping with the metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a dielectric layer on the substrate and having a hole;
a barrier layer within the hole; and
a metal layer within the hole and in contact with the barrier layer.

2. The semiconductor structure as claimed in claim 1, wherein the metal layer has an upper surface, and the semiconductor structure further comprises:
a capping layer over the upper surface of the metal upper surface.

3. The semiconductor structure as claimed in claim 2, wherein the capping layer is non-reactive capping which does not react with the metal layer.

4. The semiconductor structure as claimed in claim 2, wherein the capping layer is reactive capping with the metal layer.

5. The semiconductor structure as claimed in claim 4, wherein the capping layer comprises a plurality of chemical elements, the chemical elements are mixed with the barrier layer.

6. The semiconductor structure as claimed in claim 5, wherein the chemical elements are dispersedly distributed within the barrier layer.

7. The semiconductor structure as claimed in claim 5, wherein the chemical elements are concentrated adjacent to an interface between the metal layer and the barrier layer.

8. The semiconductor structure as claimed in claim 1, wherein the metal layer is formed of Cu-based alloy, Co based alloy, Al-based alloy, Ni-based alloy or Ag-based alloy, and the barrier layer is formed of the elements from the metal alloy that formed into the compounds comprising metal-oxide, metal-nitride, metal-carbide, metal-silicide, and metal-silicate.

9. The semiconductor structure as claimed in claim 1, wherein the barrier layer covers sidewall of the hole and the metal layer.

10. The semiconductor structure as claimed in claim 1, further comprising:
an etching stop layer over the dielectric layer;
wherein a portion of the barrier layer is disposed between the etching stop layer and the metal layer.

11. A semiconductor structure, comprising:
a substrate;
a dielectric layer on the substrate and having a hole;
a metal layer comprising a trace portion and a via portion, wherein the via portion is disposed a lower portion of the hole, the trace portion is disposed an upper portion of the hole, and the trace portion and the via portion are different in material; and
a barrier layer disposed between the trace portion and the dielectric layer.

12. The semiconductor structure as claimed in claim 11, wherein the via portion is in directly contact with the dielectric layer.

13. The semiconductor structure as claimed in claim 11, wherein the metal layer has an upper surface, and the semiconductor structure further comprises:
a capping layer over the upper surface of the metal upper surface.

14. The semiconductor structure as claimed in claim 13, wherein the capping layer is non-reactive capping which does not react with the metal layer.

15. The semiconductor structure as claimed in claim 13, wherein the capping layer is reactive capping with the metal layer.

16. The semiconductor structure as claimed in claim 15, wherein the capping layer comprises a plurality of chemical elements, the chemical elements are mixed with the barrier layer.

17. A manufacturing method for a semiconductor structure, comprising:
forming a dielectric layer on the substrate, wherein the dielectric layer has a hole;
forming a metal layer within the hole; and
forming a barrier layer within the hole, wherein the metal layer is contact with the barrier layer.

18. The manufacturing method as claimed in claim 17, wherein forming the metal layer within the hole comprises:
heating the metal layer to make the metal layer be flowable.

19. The manufacturing method as claimed in claim 17, wherein forming the barrier layer within the hole comprises:
forming the barrier layer by heating the metal layer, wherein the barrier layer is disposed between the metal layer and the dielectric layer.

20. The manufacturing method as claimed in claim 17, further comprising:
forming a capping layer over an upper surface of the metal layer;
wherein the capping layer is a reactive capping with the metal layer.
